(19) United States
(12) Patent Application Publication
(10) Pub. No.: US 2026/0293311 A1
(43) Pub. Date: Sep. 24, 2026

(54) ARRAY SUBSTRATE AND MANUFACTURING METHOD THEREFOR, AND DISPLAY APPARATUS

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Meng ZHAO, Beijing (CN); Jiao ZHAO, Beijing (CN); Haoliang ZHENG, Beijing (CN); Hao WU, Beijing (CN); Yang LV, Beijing (CN); Chaolu WANG, Beijing (CN); Rui YAN, Beijing (CN); Jianhua DU, Beijing (CN); Feng GUAN, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 19/477,519

(22) PCT Filed: Apr. 26, 2023
(86) PCT No.: PCT/CN2023/090950

§ 371 Date: Oct. 22, 2025

(51) Int. Cl. H10D 86/40; H10D 86/60

(52) U.S. Cl. CPC H10D 86/443; H10D 86/423; H10D 86/471; H10D 86/481; H10D 86/60

(57) ABSTRACT

Embodiments of the present disclosure provide an array substrate and manufacturing method thereof, and a display device, the array substrate includes: a base substrate, a thin film transistor group, and a signal shielding structure. The thin film transistor group includes first and second thin film transistors overlapped with each other in a first direction perpendicular to a main surface of the base substrate; the first thin film transistor includes a first active layer and a first gate electrode, and the second thin film transistor includes a second active layer and a second gate electrode. The signal shielding structure is located between the first and second thin film transistors, wherein an orthographic projection of the first gate electrode on the base substrate is within a range of an orthographic projection of the signal shielding structure on the base substrate.

### TECHNICAL FIELD

Embodiments of the present disclosure relate to an array substrate and a manufacturing method thereof, and a display device.

### BACKGROUND

Display devices generally include liquid crystal display devices, light-emitting diode (LED) display devices, organic light-emitting diode (OLED) display devices, and quantum-dot light-emitting diode (QLED) display devices, etc. Various display devices may include an array substrate having a pixel driving circuit, and the pixel driving circuit typically includes a plurality of thin film transistors and capacitors. With the continuous development of display technology, the resolution requirements for display devices have also increased. Generally, the resolution may be improved by reducing sub-pixel size, but problems such as signal crosstalk between adjacent thin film transistors may arise. Therefore, how to avoid signal crosstalk while improving the resolution of the display device is a problem that needs to be solved in current display technology.

For example, Micro-LED display technology is a display technology that has become increasingly popular in recent years. Due to the characteristics of the Micro-LED chip such as small size, high integration and self-illuminous, compared with LCD and OLED in display, it has greater advantages in terms of brightness, resolution, contrast, energy consumption, service life, response speed, and thermal stability. Due to the performance advantages of Micro-LED in contrast, brightness, service life, and response speed, Micro-LED display technology is highly competitive in the field of near-eye display. However, near-eye display requires a high-resolution screen. Therefore, how to improve the resolution of the Micro-LED driving circuit backplane is currently the primary issue for the application of this technology in the field of near-eye display.

### SUMMARY

Embodiments of the present disclosure provide an array substrate, including: a base substrate; a thin film transistor group, disposed on a side of the base substrate, wherein the thin film transistor group includes a first thin film transistor and a second thin film transistor, the first thin film transistor and the second thin film transistor overlap with each other in a first direction perpendicular to a main surface of the base substrate, the second thin film transistor is disposed on a side of the first thin film transistor away from the base substrate, the first thin film transistor includes a first active layer and a first gate electrode, and the second thin film transistor includes a second active layer and a second gate electrode; a signal shielding structure, disposed between the first thin film transistor and the second thin film transistor in the first direction, wherein an orthographic projection of the first gate electrode on the base substrate is within a range of an orthographic projection of the signal shielding structure on the base substrate; and a conductive connector, disposed on a side of the signal shielding structure away from the first thin film transistor and connected to the first thin film transistor through a via hole, wherein the via hole does not penetrate through the signal shielding structure, and is spaced apart from the signal shielding structure in a second direction parallel to the main surface of the base substrate.

In the array substrate provided by an embodiment of the present disclosure, an orthographic projection of at least a portion of the second gate electrode on the base substrate overlaps with the orthographic projection of the first gate electrode on the base substrate, and the orthographic projection of the at least the portion of the second gate electrode on the base substrate is within a range of the orthographic projection of the signal shielding structure on the base substrate.

In the array substrate provided by an embodiment of the present disclosure, the signal shielding structure is disposed on a side of the first gate electrode away from the first active layer and close to the second thin film transistor.

In the array substrate provided by an embodiment of the present disclosure, the signal shielding structure includes a metal shielding layer, and the metal shielding layer is connected to a direct current signal terminal.

In the array substrate provided by an embodiment of the present disclosure, the direct current signal terminal includes a power supply voltage terminal, a ground terminal, or a common voltage terminal.

In the array substrate provided by an embodiment of the present disclosure, wherein the second gate electrode includes a top gate electrode and a bottom gate electrode that are connected to each other, the top gate electrode and the bottom gate electrode are located on opposite sides of the second active layer in the first direction, and the bottom gate electrode is closer to the base substrate than the top gate electrode to the base substrate; and the metal shielding layer is located between the bottom gate electrode and the first gate electrode.

In the array substrate provided by an embodiment of the present disclosure, the second gate electrode and the metal shielding layer are located on opposite sides of the second active layer in the first direction, and the metal shielding layer is further configured to adjust a threshold voltage of the second thin film transistor by selecting a direct current signal terminal to which the metal shielding layer is connected.

In the array substrate provided by an embodiment of the present disclosure, the signal shielding structure further includes a dielectric shielding unit, and an orthographic projection of the second active layer on the base substrate is within a range of an orthographic projection of the dielectric shielding unit on the base substrate.

In the array substrate provided by an embodiment of the present disclosure, the metal shielding layer is disposed on a side of the dielectric shielding unit closer to the first thin film transistor, and the metal shielding layer extends beyond an edge of the dielectric shielding unit in a direction parallel to the main surface of the base substrate.

In the array substrate provided by an embodiment of the present disclosure, the metal shielding layer is disposed on a side of the dielectric shielding unit away from the first thin film transistor, and an orthographic projection of the metal shielding layer on the base substrate overlaps with the orthographic projection of the dielectric shielding unit on the base substrate.

In the array substrate provided by an embodiment of the present disclosure, further including: an interlayer dielectric structure, located between the first thin film transistor and the second thin film transistor in the first direction, wherein the signal shielding structure is embedded in the interlayer dielectric structure or at least includes a portion of the interlayer dielectric structure.

In the array substrate provided by an embodiment of the present disclosure, the interlayer dielectric structure includes a dielectric body part and a dielectric protrusion; the dielectric body part extends from a first region where the thin film transistor group is located to a second region of the array substrate in the second direction parallel to the base substrate, and the second region is a region other than the first region; the dielectric protrusion is located in the first region, and protrudes toward the second thin film transistor from a surface of the dielectric body part away from the first thin film transistor, and the dielectric protrusion is served as a dielectric shielding unit and used as at least a portion of the signal shielding structure; and the via hole penetrates through the dielectric body part.

In the array substrate provided by an embodiment of the present disclosure, the dielectric body part and the dielectric protrusion include different materials, and an interface is between the dielectric body part and the dielectric protrusion.

In the array substrate provided by an embodiment of the present disclosure, a dielectric constant of the dielectric protrusion is less than a dielectric constant of the dielectric body part.

In the array substrate provided by an embodiment of the present disclosure, the dielectric constant of the dielectric protrusion is less than or equal to 3.5.

In the array substrate provided by an embodiment of the present disclosure, the dielectric body part includes silicon oxide, and the dielectric protrusion includes spin-on glass.

In the array substrate provided by an embodiment of the present disclosure, the dielectric body part and the dielectric protrusion include a same material and are integrally formed.

In the array substrate provided by an embodiment of the present disclosure, the dielectric body part and the dielectric protrusion include spin-on glass.

In the array substrate provided by an embodiment of the present disclosure, the signal shielding structure further includes a metal shielding layer, the metal shielding layer is embedded in the dielectric body part and connected to a direct current signal terminal through a conductive via, and the conductive via is laterally aside the dielectric protrusion in the second direction and extends through a portion of the dielectric body part to connect to the metal shielding layer.

In the array substrate provided by an embodiment of the present disclosure, an additional metal layer is disposed on a side of the dielectric protrusion away from the dielectric body part and close to the second active layer, and the second gate electrode includes a top gate electrode located on a side of the second active layer away from the additional metal layer; wherein the additional metal layer is connected to a direct current signal terminal and served as a metal shielding layer of the signal shielding structure; or the additional metal layer is connected to the top gate electrode, so as to be served as a bottom gate electrode of the second thin film transistor.

In the array substrate provided by an embodiment of the present disclosure, further including: a capacitor, disposed on the base substrate and disposed side by side with the first thin film transistor and the signal shielding structure in a direction parallel to the main surface of the base substrate, wherein the capacitor includes a first electrode plate and a second electrode plate that are opposite to each other, wherein the array substrate further includes a first metal material layer, an insulation layer, and a second metal material layer, and the insulation layer is located between the first metal material layer and the second metal material layer; the first electrode plate and the first gate electrode are located in the first metal material layer, and the second electrode plate is located in the second metal material layer; and the signal shielding structure includes at least one of a metal shielding layer and a dielectric shielding unit, and the dielectric shielding unit is located on a side of the insulation layer away from the first metal material layer.

In the array substrate provided by an embodiment of the present disclosure, the metal shielding layer and the second metal material layer are located in a same layer.

In the array substrate provided by an embodiment of the present disclosure, including a first region and a second region, wherein the thin film transistor group is located in the first region, the capacitor is located in the second region, and the second metal material layer extends continuously from the first region to the second region, and is used as both the metal shielding layer and the second electrode plate.

In the array substrate provided by an embodiment of the present disclosure, including a plurality of thin film transistor groups arranged in an array, and each of the plurality of thin film transistor groups is configured to be formed in one sub-pixel driving circuit.

In the array substrate provided by an embodiment of the present disclosure, the thin film transistor group includes a first thin film transistor sub-group and a second thin film transistor sub-group arranged side by side in a direction parallel to the base substrate; the first thin film transistor sub-group includes the first thin film transistor and the second thin film transistor; the second thin film transistor sub-group includes a third thin film transistor and a fourth thin film transistor overlapped in the first direction, and an additional signal shielding structure is disposed between the third thin film transistor and the fourth thin film transistor.

In the array substrate provided by an embodiment of the present disclosure, the first active layer and the second active layer include different materials.

In the array substrate provided by an embodiment of the present disclosure, the first active layer includes polysilicon, and the second active layer includes oxide semiconductor.

An embodiment of the present disclosure provides a display device, including any one of the array substrates, and a light-emitting device, wherein the light-emitting device is connected to a sub-pixel driving circuit including the thin film transistor group, and the sub-pixel driving circuit is configured to drive the light-emitting device to emit light.

In the display device provided by an embodiment of the present disclosure, the light-emitting device includes an inorganic light-emitting diode chip or includes an organic light-emitting layer.

An embodiment of the present disclosure provides a method of manufacturing an array substrate, including: providing a base substrate; forming a first thin film transistor on the base substrate, wherein the first thin film transistor includes a first active layer and a first gate electrode; forming a signal shielding structure on a side of the first thin film transistor away from the base substrate; forming a second thin film transistor on a side of the signal shielding structure away from the first thin film transistor, wherein the second thin film transistor includes a second active layer and a second gate electrode; and forming a conductive connector, wherein the conductive connector is located on the side of the signal shielding structure away from the first thin film transistor, and is connected to the first thin film transistor through a via hole, and the via hole is located outside the signal shielding structure, and is spaced apart from the signal shielding structure in a direction parallel to the base substrate; wherein the first thin film transistor and the second thin film transistor overlap with each other in a first direction perpendicular to a main surface of the base substrate and constitute a thin film transistor group, the signal shielding structure is located between the first thin film transistor and the second thin film transistor in the first direction, and an orthographic projection of the first gate electrode on the base substrate is within a range of an orthographic projection of the signal shielding structure on the base substrate.

In the method of manufacturing the array substrate provided by an embodiment of the present disclosure, further including: forming a first metal material layer on a side of the first active layer away from the base substrate, wherein the first gate electrode is located in the first metal material layer; forming an insulation layer on a side of the first metal material layer away from the first active layer; and forming an interlayer dielectric structure on a side of the insulation layer away from the first metal material layer, wherein the signal shielding structure includes at least one of a metal shielding layer and a portion of the interlayer dielectric structure.

In the method of manufacturing the array substrate provided by an embodiment of the present disclosure, the interlayer dielectric structure includes a dielectric body part and a dielectric protrusion, and forming the interlayer dielectric structure includes: forming a first dielectric layer on the insulation layer to be served as the dielectric body part; forming a second dielectric layer on the first dielectric layer; and patterning the second dielectric layer to remove a portion of the second dielectric layer outside a first region where the thin film transistor group is located and remain a portion of the second dielectric layer in the first region to be served as the dielectric protrusion, wherein the dielectric protrusion is served as at least a portion of the signal shielding structure.

In the method of manufacturing the array substrate provided by an embodiment of the present disclosure, the interlayer dielectric structure includes a dielectric body part and a dielectric protrusion, and forming the interlayer dielectric structure includes: forming a planarization dielectric layer on the insulation layer; thinning a portion of the planarization dielectric layer, so as to form the dielectric body part with a first thickness and the dielectric protrusion with a second thickness, wherein the second thickness is greater than the first thickness, and the dielectric protrusion is located in a region where the thin film transistor group is located, and is served as at least a portion of the signal shielding structure.

In the method of manufacturing the array substrate provided by an embodiment of the present disclosure, the metal shielding layer is formed before forming the interlayer dielectric structure, and the metal shielding layer is embedded in the dielectric body part.

In the method of manufacturing the array substrate provided by an embodiment of the present disclosure, after forming the interlayer dielectric structure, an additional metal layer is formed on a side of the dielectric protrusion away from the dielectric body part.

In the method of manufacturing the array substrate provided by an embodiment of the present disclosure, the additional metal layer is connected to a direct current signal terminal, and is served as the metal shielding layer; or the second gate electrode includes a top gate electrode located on a side of the second active layer away from the additional metal layer, the additional metal layer is connected to the top gate electrode, and is served as a bottom gate electrode of the second thin film transistor.

In the method of manufacturing the array substrate provided by an embodiment of the present disclosure, forming the signal shielding structure includes: forming a second metal material layer on a side of the insulation layer away from the first metal material layer before forming the interlayer dielectric structure, wherein the second metal material layer includes the metal shielding layer, and the interlayer dielectric structure covers the second metal material layer.

In the method of manufacturing the array substrate provided by an embodiment of the present disclosure, further including: forming a capacitor, wherein the capacitor is disposed side by side with the first thin film transistor and the signal shielding structure, and the capacitor includes a first electrode plate and a second electrode plate that faces each other; wherein the first electrode plate and the second electrode plate are located in the first metal material layer and the second metal material layer, respectively.

In the method of manufacturing the array substrate provided by an embodiment of the present disclosure, forming the metal shielding layer and the second electrode plate includes: patterning the second metal material layer to form the metal shielding layer and the second electrode plate that are separated from each other; or the second metal material layer extends continuously from a region where the thin film transistor group is located to a region where the capacitor is located, and is used as both the metal shielding layer and the second electrode plate.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1 illustrates a schematic cross-sectional view of an array substrate according to some embodiments of the present disclosure.

FIG. 2 illustrates a schematic cross-sectional view of an array substrate according to some other embodiments of the present disclosure.

FIG. 3A to FIG. 3J illustrate schematic cross-sectional views of a method of manufacturing an array substrate according to some embodiments of the present disclosure.

FIG. 4 to FIG. 6 illustrate schematic cross-sectional views of an array substrate according to some other embodiments of the present disclosure.

FIG. 7A to FIG. 7H illustrate schematic cross-sectional views of a method of manufacturing an array substrate according to some other embodiments of the present disclosure;

FIG. 8 to FIG. 10 illustrate schematic cross-sectional views of an array substrate according to some other embodiments of the present disclosure.

FIG. 11A to FIG. 11C illustrate schematic cross-sectional views of a method of manufacturing an array substrate according to some other embodiments of the present disclosure;

FIG. 12 and FIG. 13 illustrate schematic cross-sectional views of an array substrate according to some other embodiments of the present disclosure.

FIG. 14 illustrates a schematic block diagram of an array substrate according to some embodiments of the present disclosure.

FIG. 15A illustrates a schematic block diagram of a display device according to some embodiments of the present disclosure.

FIG. 15B illustrates a schematic diagram of a sub-pixel driving circuit according to some embodiments of the present disclosure.

FIG. 16 illustrates a schematic block diagram of a display device according to some other embodiments of the present disclosure.

FIG. 17 illustrates a scanning electron microscope (SEM) image of an array substrate according to some embodiments of the present disclosure.

FIG. 18 is a schematic top view of gate electrodes of respective thin film transistors of a thin film transistor group and a signal shielding structure in an array substrate according to some embodiments of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., used in the present disclosure are not intended to indicate any sequence, amount or importance, but distinguish different components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not limited to a physical connection or mechanical connection, but may also include an electrical connection, directly or indirectly.

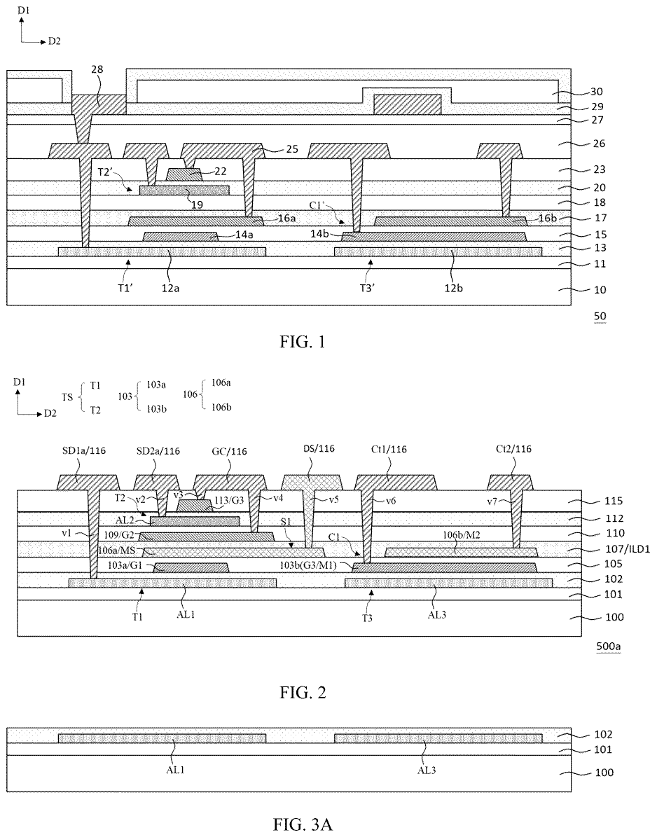

FIG. 1 illustrates a schematic cross-sectional view of an array substrate according to some embodiments of the present disclosure.

Referring to FIG. 1, in some embodiments, an array substrate 50 includes a base substrate 10 and a plurality of thin film transistors disposed on the base substrate 10, and some of the plurality of thin film transistors may overlap with each other in a direction perpendicular to a main surface of the base substrate 10. For example, the plurality of thin film transistors may include a thin film transistor T1′, a thin film transistor T2′, and a thin film transistor T3′. In some embodiments, the thin film transistor T1′ and the thin film transistor T3′ may be top-gate thin film transistors, and the thin film transistor T2′ may be a dual-gate transistor. For example, the thin film transistor T1′ may include a gate electrode 14a and an active layer 12a; the thin film transistor T3′ may include a gate electrode 14b and an active layer 12b; the thin film transistor T2′ may include a bottom gate electrode 16a, a top gate electrode 16b, and an active layer 19. The active layers 12a, 12b, and 19 of the thin film transistors T1′-T3′ each include a source region, a drain region, and a channel region, where the channel region is located between the source region and the drain region. In some embodiments, the thin film transistors T1′ and T3′ may be disposed in the same layer, that is, their gate electrodes may be disposed in the same layer and their active layers may be disposed in the same layer. In the present disclosure, a plurality of components “disposed in the same layer” means that the plurality of components are in the same layer, have the same material, or are patterned from the same material layer; that is, the gate electrodes 12a and 12b may be formed from the same metal material layer through a patterning process, and the active layers 14a and 14b may be formed from the same active material layer through a patterning process. The thin film transistor T2′ may be disposed on a side of the thin film transistor T1′ away from the base substrate 10, and overlap with the thin film transistor T1′ in the direction perpendicular to the main surface of the base substrate 10. In the present disclosure, a plurality of components overlapping with each other in a certain direction means that the orthographic projections of the plurality of components on the same reference plane in the direction overlap with each other, where the direction is perpendicular to the reference plane. That is to say, the thin film transistors T1′ and T2′ overlap with each other in a direction (e.g., the direction D1) perpendicular to the base substrate 10, which means that orthographic projections of the thin film transistors T1′ and T2′ on the base substrate 10 in the direction D1 overlap with each other.

In some embodiments, the array substrate 50 further includes a capacitor C1′, which includes a first electrode plate and a second electrode plate 16b facing each other; for example, the first electrode plate of the capacitor C1′ may share the same metal layer with the gate electrode 14b of the thin film transistor T2′, that is, at least a portion of the metal layer where the gate electrode 14b is located may be also used as the first electrode plate of the capacitor C1′; and the second electrode plate 16b of the capacitor C1′ may be disposed in the same layer with the bottom gate electrode 16a of the thin film transistor T2′.

In some embodiments, a buffer layer 11 may be disposed between the thin film transistors T1′ and T3′ and the base substrate 10, and an insulation layer 13, a dielectric layer 15, an insulation layer 17, a buffer layer 18, an insulation layer 20, an interlayer dielectric layer 23 may be disposed on a side of the buffer layer 11 away from the base substrate 10. A conductive layer 25 is disposed on the interlayer dielectric layer 23 and includes a plurality of conductive connectors connected to respective thin film transistors and capacitors through via holes.

In some embodiments, one or more planarization dielectric layers and passivation layers and a conductive layer 28 are further disposed on the conductive layer 25. For example, the conductive layer 28 may include one or more conductive connectors, and the conductive connectors are electrically connected to the conductive layer 25 through via holes in the planarization dielectric layer 26 and the passivation layer 27. One or more passivation layers 29 and a planarization dielectric layer 30 may be disposed on the conductive layer 28, and the conductive layer 28 has a portion exposed by an opening of the passivation layer 29.

In some embodiments, the thin film transistors T1′ and T2′ and/or the thin film transistor T2′ and the capacitor C1′ are included in the same sub-pixel driving circuit. By stacking the thin film transistors T1′ and T2′, the lateral occupied area of the sub-pixel driving circuit and the sub-pixel may be reduced, that is, the pixel size is reduced, thereby improving the resolution of the display device. In the present disclosure, the stacking of a plurality of thin film transistors means that the plurality of thin film transistors overlap with each other in a direction perpendicular to the base substrate. In some embodiments, the thin film transistor T1′ is, for example, a low temperature polysilicon (LTPS) thin film transistor, which can use polysilicon material as the active layer material; the thin film transistor T3′ may be an oxide thin film transistor, which uses indium gallium zinc oxide (IGZO) or the like as the active layer material, but the present disclosure is not limited thereto. For example, the thin film transistor T3′ is served as a switching transistor. In some embodiments, compared with using a LTPS thin film transistor as a switching transistor, using an oxide thin film transistor as a switching transistor may significantly reduce leakage current, thereby reducing the size of corresponding capacitor and reducing the pixel area, which can further improve the resolution of the display device.

However, in this embodiment, gate signal lines of the thin film transistors T1′ and T2′ overlap with each other in the direction D1, and signal crosstalk may exist between adjacent gate signal lines. For example, the transition of the gate electrode 14a of the thin film transistor T1′ may affect and drive the transition of the gate electrodes 16a and 22 of the thin film transistor T2′, thereby affecting the operating state of the thin film transistor T2′.

In order to solve the problem of signal crosstalk between stacked thin film transistors, various embodiments of the present disclosure provide an array substrate, which includes a thin film transistor group, and the thin film transistor group includes a plurality of thin film transistors overlapping with each other in a direction perpendicular to the main surface of the base substrate; a signal shielding structure is disposed between adjacent thin film transistors among the plurality of thin film transistors to shield signal crosstalk between adjacent thin film transistors, for example, to prevent the transition of the gate signal of one of adjacent thin film transistors from affecting or driving the transition of the gate signal of the other one of adjacent thin film transistors, and/or to prevent the transition of the gate signal of one of adjacent thin film transistors from affecting the channel region of the active layer of the other one of adjacent thin film transistors. For example, the thin film transistor group includes a first thin film transistor and a second thin film transistor that are stacked, the second thin film transistor is disposed on a side of the first thin film transistor away from the base substrate, and the signal shielding structure is disposed between the first thin film transistor and the second thin film transistor in a direction perpendicular to the main surface of the base substrate. For example, the orthographic projection of a first gate electrode of the first thin film transistor on the base substrate may be located within a range of the orthographic projection of the signal shielding structure on the base substrate, which can prevent the transition of the gate signal of the first thin film transistor from adversely affecting the gate signal of the second thin film transistor or from inducing a transition of the gate electrode of the second thin film transistor, and/or can prevent the transition of the gate signal of the first thin film transistor from affecting the channel region of the active layer of the second thin film transistor.

In the present embodiment, by stacking thin film transistors and providing the signal shielding structure between adjacent thin film transistors, signal crosstalk between adjacent thin film transistors can be prevented on the basis of reducing device size (for example, reducing pixel size to improve resolution), thereby ensuring the normal operation and reliability of the thin-film transistors, and thus satisfying the display functions of high-resolution display devices. In various embodiments, the signal shielding structure may include at least one of a metal shielding layer and a dielectric shielding unit; the metal shielding layer is connected to a direct current signal terminal, and the dielectric shielding unit may include a dielectric material with a low dielectric constant and has sufficient thickness, so that the signal shielding structure has good signal shielding capabilities.

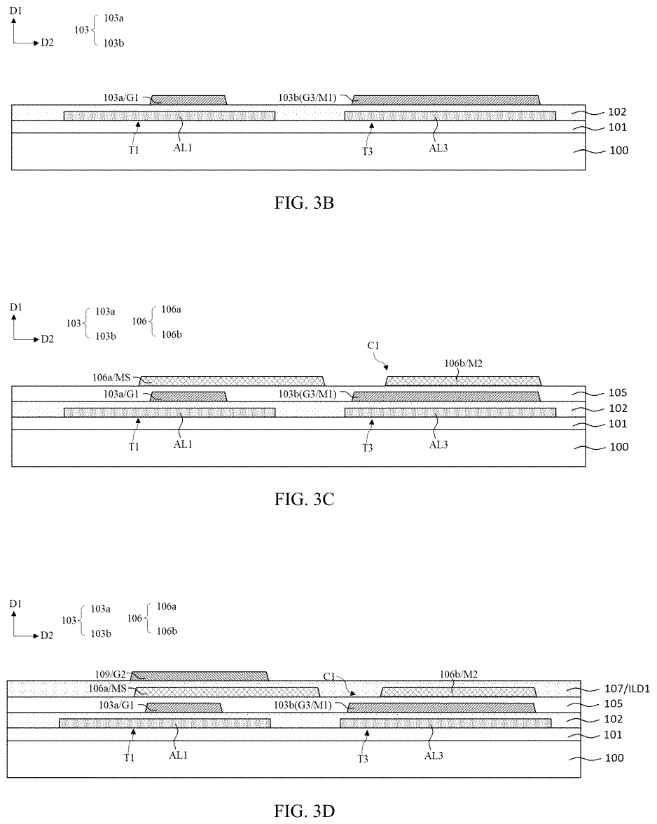

FIG. 2 illustrates a schematic cross-sectional view of an array substrate according to some embodiments of the present disclosure.

Referring to FIG. 2, in some embodiments, an array substrate 500a includes a base substrate 100 and a thin film transistor group TS disposed on the base substrate 100. The thin film transistor group TS may include a plurality of thin film transistors that are stacked. The plurality of thin film transistors overlap with each other (e.g., at least partially overlap with each other) in a direction perpendicular to the main surface of the base substrate 100. For example, the thin film transistor group TS may include a thin film transistor T1 and a thin film transistor T2. The thin film transistors T1 and T2 overlap with each other in the direction perpendicular to the main surface of the base substrate 100 (e.g., a direction D1), that is, the orthographic projection of the thin film transistor T1 on the base substrate 100 in the direction D1 overlaps with the orthographic projection of the thin film transistor T2 on the base substrate 100 in the direction D1. For example, the thin film transistor T2 may be disposed on a side of the thin film transistor T1 away from the base substrate 100. The thin film transistors T1 and T2 may be referred to as a first thin film transistor and a second thin film transistor, respectively.

It should be understood that, the number of thin film transistors included in the thin film transistor group TS shown in the figure is only for illustration, and the present disclosure is not limited thereto. For example, in some other embodiments, the thin film transistor group TS may include more than two thin film transistors. The plurality of thin film transistors in the thin film transistor group TS may be included in the same one sub-pixel driving circuit, and the thin film transistor group TS may include a plurality of thin film transistor sub-groups disposed side by side in a direction parallel to the main surface of the base substrate 100, each thin film transistor sub-group includes two thin film transistors that are stacked.

In some embodiments, a signal shielding structure is disposed between adjacent thin film transistors in the thin film transistor group TS to shield signal crosstalk, such as electrical signal crosstalk, between adjacent thin film transistors. It should be understood that adjacent thin film transistors refer to thin film transistors adjacent to each other in the direction perpendicular to the main surface of the base substrate 100 (e.g., direction D1). The figure schematically illustrates a signal shielding structure S1 disposed between the thin film transistors T1 and T2. In other embodiments in which the thin film transistor group TS includes more than two thin film transistors, the array substrate 500a may include a plurality of signal shielding structures S1, and the plurality of signal shielding structures S1 are each disposed between corresponding two adjacent thin film transistors, that is, every two adjacent and stacked thin film transistors in the thin film transistor group may be disposed with a signal shielding structure therebetween, so as to shield signal crosstalk between adjacent thin film transistors.

In some embodiments, as shown in FIG. 2, the thin film transistor T1 includes a gate electrode G1, an active layer AL1, and a gate insulation layer between the gate electrode G1 and the active layer AL1. In the present disclosure, the active layer of each thin film transistor includes a source region, a drain region, and a channel region, the source region and the drain region may be interchanged with each other, and the source region and the drain region may be collectively referred to as the source/drain region. For the sake of simplicity of the drawings, the source/drain region and channel region of each active layer are not specifically shown in the figure, but it should be understood that, the channel region is between the source region and the drain region, and overlaps with the gate electrode in the direction perpendicular to the main surface of the base substrate. In some embodiments, the thin film transistor T1 may have a top-gate structure, that is, the gate electrode G1 is disposed on a side of the active layer AL1 away from the base substrate 100. That is to say, the gate electrode G1 is closer to the thin film transistor T2 than the active layer AL1 to the thin film transistor T2.

In some embodiments, the thin film transistor T2 may be a dual-gate transistor and include a gate electrode G2, a gate electrode G3, an active layer AL2, and gate insulation layers between each of the gate electrodes G2 and G3 and the active layer AL2. The gate electrodes G2 and G3 are connected to each other and are disposed on opposite sides of the active layer AL2 in the direction perpendicular to the main surface of the base substrate 100. In some embodiments, the gate electrode G2 is closer to the base substrate 100 than the gate electrode G3 to the base substrate 100. The gate electrode G2 and the gate electrode G3 may also be referred to as the bottom gate electrode and the top gate electrode of the thin film transistor T2, respectively. Each gate electrode of the plurality of thin film transistors may be connected to a corresponding gate signal line. For example, each gate electrode may be located in the same layer as the gate signal line, and a portion of the gate signal line is used as the gate electrode of the thin film transistor.

In some embodiments, the active layers AL1 and AL2 of the thin film transistors T1 and T2 are respectively referred to as a first active layer and a second active layer, the gate electrode G1 of the thin film transistor T1 is referred to as a first gate electrode, and the gate electrode G2/G3 of the thin film transistor T2 is referred to as a second gate electrode; in this embodiment, the second gate electrode of the thin film transistor T2 includes a bottom gate electrode G2 and a top gate electrode G3, but the present disclosure is not limited thereto. In some other embodiments, the second gate electrode may also include only the top gate G3 electrode or only the bottom gate electrode G2.

In some embodiments, the thin film transistor T1 may be a low temperature polysilicon (LTPS) thin film transistor, and uses low temperature polysilicon as the material of the active layer AL1; and the thin film transistor T2 may be an oxide thin film transistor, and uses an oxide semiconductor such as IGZO as the material of the active layer AL2, but the present disclosure is not limited thereto. The thin film transistors T1 and T2 may each be selected from one of an LTPS thin film transistor and an oxide thin film transistor, and the thin film transistors T1 and T2 may be the same type or different types of thin film transistors. In some embodiments, the thin film transistor T2 is served as a switching transistor in a pixel driving circuit, and the thin film transistor T2 using an oxide semiconductor material such as IGZO can reduce leakage current.

Still referring to FIG. 2, the signal shielding structure S1 is disposed between the thin film transistors T1 and T2 in the direction D1 perpendicular to the main surface of the base substrate 100 to shield the signal crosstalk between the thin film transistors T1 and T2, for example, shield crosstalk between gate signals of the thin film transistors T1 and T2. For example, the gate electrode G1 of the thin film transistor T1 and the gate electrode G2/G3 of the thin film transistor T2 at least partially overlap in the direction perpendicular to the main surface of the base substrate 100, and the signal shielding structure S1 is at least disposed between the overlapping portions of the gate electrode G1 and the gate electrode G2. For example, the orthographic projection of the gate electrode G1 of the thin film transistor T1 on the base substrate 100 may be located within a range of the orthographic projection of the signal shielding structure S1 on the base substrate 100, thereby preventing the signal transition of the gate electrode G1 of the thin film transistor T1 from adversely affecting the gate electrode G2/G3 of the thin film transistor T2; the orthographic projection of at least a portion of the gate electrode G2/G3 of the thin film transistor T2 on the base substrate 100 overlaps with the orthographic projection of the gate electrode G1 of the thin film transistor T1 on the base substrate 100, and the orthographic projection of at least the portion of the gate electrode G2/G3 on the base substrate 100 is located within the orthographic projection of the signal shielding structure S1 on the base substrate 100, thereby preventing the signal transition of the gate electrode G2/G3 of the thin film transistor T2 from adversely affecting the gate electrode G1 of the thin film transistor T1. In some embodiments, the orthographic projection of the gate electrode G2/G3 of the thin film transistor T2 on the base substrate 100 may be entirely within a range of the orthographic projection of the signal shielding structure S1 on the base substrate 100. Herein, the orthographic projection of a component on the base substrate 100 refers to a projection of the component on the main surface of the base substrate in the direction (e.g., direction D1) perpendicular to the main surface of the base substrate.

In some embodiments, the signal shielding structure S1 is disposed on a side of the gate electrode G1 of the thin film transistor S1 away from the active layer AL1 and close to the thin film transistor T2. For example, the signal shielding structure S1 is located between the gate electrode G1 of the thin film transistor T1 and the bottom gate electrode G2 of the thin film transistor T2. In some embodiments, the gate electrode G1 is a portion of a first gate signal line, the gate electrode G2/G3 is a portion of a second gate signal line, and the first gate signal line at least partially overlaps with the second gate signal line in the direction perpendicular to the main surface of the base substrate 100; and in the direction perpendicular to the main surface of the base substrate 100, the signal shielding structure S1 is disposed at least between the portions of the first gate signal line and the second gate signal line that overlap with each other, and the orthographic projections of the overlapping portions of the first gate signal line and the second gate signal line on the main surface of the base substrate 100 may be located within a range of the orthographic projection of the signal shielding structure S1 on the main surface of the base substrate 100. For example, the orthographic projection of the first gate signal line on the main surface of the base substrate 100 is located within a range of the orthographic projection of the signal shielding structure S1 on the main surface of the base substrate, the orthographic projection of at least a portion of the second gate signal line on the base substrate overlaps with the orthographic projection of the first gate signal line on the base substrate, and the orthographic projection of the at least the portion of the second gate signal line on the base substrate is located within a range of the orthographic projection of the signal shielding structure S1 on the main surface of the base substrate. The extending directions of the first gate signal line and the second gate signal line may be the same as or different from each other.

In some embodiments, the signal shielding structure S1 may be or include a metal shielding layer MS, and the metal shielding layer MS is connected to a direct current (DC) signal terminal, which may include a power supply voltage terminal, a ground terminal, a common voltage terminal, etc. For example, the metal shielding layer MS may be connected to ground, OV voltage, or a stable DC power supply voltage terminal such as VDD or VSS. For example, the metal shielding layer 106a is connected to a direct current signal layer DS, and the direct current signal layer DS is configured to connecting the metal shielding layer 106a to ground or OV voltage, or to apply a DC voltage signal such as VDD, VSS, etc. to the metal shielding layer 106a. By providing the metal shielding layer MS between the thin film transistors T1 and T2, and connecting the metal shielding layer MS to a stable direct current signal terminal, the signal crosstalk between the thin film transistors T1 and T2 can be shielded. For example, it can prevent the signal transition on the gate signal line where the gate electrode G1 is located from affecting the gate electrodes G2 and G3, or even causing the gate electrodes G2 and G3 to transition, or prevent the signal transition on the gate signal line where the gate electrode G2/G3 is located from affecting the gate electrode G1, or even causing the gate electrode G1 to transition, thereby ensuring that the thin film transistors T1 and T2 operate independently and without interference with each other, thereby improving the reliability of the thin film transistors T1 and T2.

In some embodiments, the array substrate 500a may further include a thin film transistor T3 and a capacitor C1. The thin film transistor T3 may include a gate electrode G3, an active layer AL3, and a gate insulation layer between the gate electrode G3 and the active layer AL3. The capacitor C1 may include an electrode plate M1 and an electrode plate M2 facing each other, and an inter-electrode insulation layer between the electrode plate M1 and the electrode plate M2.

For example, the thin film transistor T3 and the capacitor C1 may be stacked and may be laterally aside the thin film transistor group TS in a direction (e.g., a direction D2) parallel to the main surface of the base substrate 100. For example, the thin film transistor T3 may be laterally aside the thin film transistor T1 in the direction D2; the gate electrode G3 and the active layer AL3 of the thin film transistor T3 may be disposed in the same layer as the gate electrode G1 and the active layer AL1 of the thin film transistor T1, respectively. The capacitor C1 is arranged side by side with the thin film transistor T1 and the signal shielding structure S1 in the direction parallel to the main surface of the base substrate. For example, the capacitor C1 may be laterally aside the thin film transistor T1 and the metal shielding layer MS in the direction D2, and the electrode plates M1 and M2 of the capacitor C1 may be disposed in the same layer as the gate electrode G1 and the metal shielding layer MS, respectively.

In some embodiments, the array substrate 500a, from bottom to top, may include a first active material layer, a metal material layer 103 (or may be referred to as a first metal material layer), a metal material layer 106 (or may be referred to as a second metal material layer), a metal material layer 109 (or may be referred to as a third metal material layer), a second active material layer, and a metal material layer 113 (or may be referred to as a fourth metal material layer). The active layers AL1 and AL3 of the thin film transistors T1 and T3 may be located in the first active material layer. The gate electrodes G1 and G3 of the thin film transistors T1 and T3, and the electrode plate M1 of the capacitor C1 may be located in the metal material layer 103. For example, the metal material layer 103 may include a metal layer 103a and a metal layer 103b separated from each other. At least a portion of the metal layer 103a is served as the gate electrode G1, and at least a portion of the metal layer 103b is served as the gate electrode G3, and may be simultaneously used as the electrode plate M1. That is to say, the gate electrode G3 and the electrode plate M1 may share the same one metal layer 103b. However, the present disclosure is not limited thereto. The metal shielding layer MS and the electrode plate M2 may be located in the metal material layer 106. For example, the metal material layer 106 may include a metal layer 106a and a metal layer 106b separated from each other. At least a portion of the metal layer 106a is served as the metal shielding layer MS, and at least a portion of the metal layer 106b is served as the electrode plate M2. In some embodiments, through disposing the metal shielding layer MS in the metal material layer 106 and in the same layer as the electrode plate M2, the metal shielding layer can be formed without increasing the number of masks.

The bottom gate electrode G2, the active layer AL2, and the top gate electrode G3 of the thin film transistor 109 may be located in the metal material layer 109, the second active material layer, and the metal material layer 113, respectively. That is to say, at least a portion of the metal material layer 109 is served as the gate electrode G2, at least a portion of the second active material layer is the active layer AL2, and at least a portion of the metal material layer 113 is served as the gate electrode G2. It should be understood that, each of the above-mentioned active material layers may be further disposed with active layer(s) of other thin film transistor(s), and each of the above-mentioned metal material layers may be further disposed with gate electrode(s) of other thin film transistor(s) or other metal components. The metal layer in which each gate electrode is located may be or include a gate signal line extending in the horizontal direction, and a portion of the gate signal line is served as the gate electrode, that is, the gate electrode and the gate signal line may share the same metal layer.

In some embodiments, each of the above-mentioned active material layers and metal material layers is embedded in a dielectric/insulation material layer, and adjacent layers of the active material layers and the metal material layers are separated by dielectric/insulation material positioned therebetween. For example, the dielectric/insulation material includes a buffer layer 101, an insulation layer 102, an insulation layer 105, a dielectric layer 107, a buffer layer 110, an insulation layer 112, and a dielectric layer 115 arranged sequentially from bottom to top on the base substrate 100. The buffer layer 101 may be located between the plurality of thin film transistors T1-T3 and the capacitor C1, and the base substrate 100. For example, the first active material layer is disposed on a side of the buffer layer 101 away from the base substrate 100; and the first active material layer (e.g., the active layers AL1 and AL3), the metal material layer 103, the metal material layer 106, the metal material layer 109, the second active material layer (e.g., the active layer AL2) , and the metal material layer 113 are respectively embedded in the insulation layer 102, the insulation layer 105, the dielectric layer 107, the buffer layer 110, the insulation layer 112, and the dielectric layer 115.

Some portions of the insulation layer 102 are located between the first active material layer and the metal material layer 103, and are served as gate insulation layers of the thin film transistors T1 and T3. For example, a portion of the insulation layer 102 is located between the active layer AL1 and the gate electrode G1, to be served as the gate insulation layer of the thin film transistor T1; and another portion of the insulation layer 102 is located between the active layer AL3 and the gate electrode G3, to be served as the gate insulation layer of the thin film transistor T3.

Some portions of the insulation layer 105 are located between the metal material layer 103 and the metal material layer 106. For example, a portion of the insulation layer 105 is located between the metal shielding layer MS and the gate electrode G2, and separates the metal shielding layer MS and the gate electrode G2 from each other; and another portion of the insulation layer 105 is located between the electrode plate MI and the electrode plate M2, and is served as the inter-electrode insulation layer of the capacitor C1.

In some embodiments, the dielectric layer 107 is served as an interlayer dielectric structure ILD1, and is located between the thin film transistors T1 and T2; and the metal shielding layer MS of the signal shielding structure S1 is embedded in the interlayer dielectric structure ILD1. A portion of the dielectric layer 107 is located between the metal shielding layer MS and the bottom gate electrode G2 of the thin film transistor T2 to separate the metal shielding layer MS and the gate electrode G2 from each other.

A portion of the buffer layer 110 is located between the bottom gate G2 and the active layer AL2, and is served as a bottom gate insulation layer of the thin film transistor T2; and a portion of the insulation layer 112 is located between the top gate electrode G3 and the active layer AL2, and is served as a top gate insulation layer of the thin film transistor T2.

In some embodiments, the insulation layers 102/105, the buffer layer 110, and the insulation layer 112 may include insulation materials such as silicon oxide, silicon nitride, silicon oxynitride, or high dielectric constant materials such as hafnium oxide. Because portions of these layers are served as gate insulation layers and/or inter-electrode insulation layers, using materials with a high dielectric constant may reduce leakage current of the corresponding thin-film transistor or increase the capacitance of capacitor. In some embodiments, the interlayer dielectric structure ILD1 (e.g., the dielectric layer 107) may include a dielectric material such as silicon oxide, spin-on glass (SOG), or the like. The interlayer dielectric structure ILD1 may be formed of a low dielectric constant material, thereby reducing the parasitic capacitance between adjacent metal layers in the direction D1. In some embodiments, the dielectric constant of the interlayer dielectric structure ILD1 may be less than or equal to the dielectric constants of the insulation layer 102/105, the buffer layer 110, and the insulation layer 112.

The dielectric layer 115 is located on the insulation layer 112 and covers the metal material layer 113. In some embodiments, the dielectric layer 115 is a planarization layer and has a flat surface at a side away from the insulation layer 112. In some embodiments, a conductive layer 116 is disposed on the dielectric layer 115. The conductive layer 116 includes conductive connectors connected to respective thin film transistors, capacitor(s), metal shielding layer(s), and spaced apart from each other. Each conductive connector is connected to a corresponding thin film transistor, capacitor, or metal shielding layer through a via hole in one or more insulation material layers (e.g., one or more of the insulation layer 112 to the dielectric layer 115). For example, the conductive connectors include a source/drain electrode SD1a, a source/drain electrode SD2a, a conductive connector GC, a direct current signal layer DS, and conductive connectors Ct1 and Ct2. It should be understood that, the source/drain electrode may be a source electrode connected to a source region of an active layer or a drain electrode connected to a drain region of an active layer, and only part of the source/drain electrodes of the thin film transistors are schematically shown in the figure.

In some embodiments, some conductive connectors (e.g., source/drain electrode SD1a) are located on a side of the signal shielding structure S1 away from the first thin film transistor T1 and are connected to the first thin film transistor T1 through via holes. The via holes are located on an outer side the signal shielding structure S1 and are spaced apart from the signal shielding structure S1 in the direction parallel to the base substrate 100, that is, the via holes do not penetrate through the signal shielding structure S1. The via holes extend through insulation material layers such as the dielectric layer 115, the insulation layer 112, the buffer layer 110, the dielectric layer 107, the insulation layer 105 and/or the insulation layer 102, so that the conductive connectors are connected to corresponding components of the thin film transistor T1.

In some embodiments, the source/drain electrode SD1a is connected to the source/drain region of the active layer AL1 through a conductive via v1; the source/drain electrode SD2a is connected to the source/drain region of the active layer AL2 through a conductive via v2; the conductive connector GC is connected to the gate electrode G3 through a conductive via v3 and connected to the gate electrode G2 through a conductive via v4, that is to say, the gate electrode G2 and the gate electrode G3 of the thin film transistor T2 are electrically connected to each other through the conductive connector GC; the conductive connector Ct1 is connected to the metal layer 103b through a conductive via v6, that is, connected to the gate electrode G3 of the thin film transistor T3 and the electrode plate M1 of the capacitor C1; and the conductive connector Ct2 is connected to the electrode plate M2 of the capacitor C1 through a conductive via v7. Each conductive via is a portion of a conductive material layer that fills a corresponding via hole of the insulation/dielectric material layer.

The direct current signal layer DS is connected to the metal shielding layer MS through a conductive via v5, so that the metal shielding layer MS can achieve the signal shielding effect. In some embodiments, the direct current signal layer DS may be or be connected to a direct current signal terminal such as a power supply voltage terminal, a ground terminal, a common voltage terminal, etc. ; for example, the direct current signal layer DS may be a power supply voltage signal line such as VDD, VSS, a OV voltage signal line, a ground signal line, etc.

In some embodiments, similar to the embodiment shown in FIG. 1, other layers such as conductive layer(s), planarization layer(s), passivation layer(s), etc., may be further disposed on the conductive layer 116 of this embodiment, and are not shown and described again here for the sake of brevity.

In this embodiment, the metal shielding layer MS is disposed between the thin film transistors T1 and T2 stacked in the thin film transistor group TS, and the metal shielding layer MS is connected to the direct current signal terminal to serve as a signal shielding structure S1, so as to shield the signal crosstalk between the thin film transistors T1 and T2, which can, for example, prevent the transition of the gate signal of one of the thin film transistors T1 and T2 from affecting the gate signal of the other one of the thin film transistors T1 and T2, or causing transition of the gate signal of the other one of the thin film transistors T1 and T2. In this way, on the basis of disposing the thin film transistor group to reduce the pixel size, the respective thin film transistors in the thin film transistor group can operate stably and independent of each other and, without interfering with each other, thereby improving the reliability of the array substrate and a display device including the same, and achieving stable display function of a high-resolution display device.

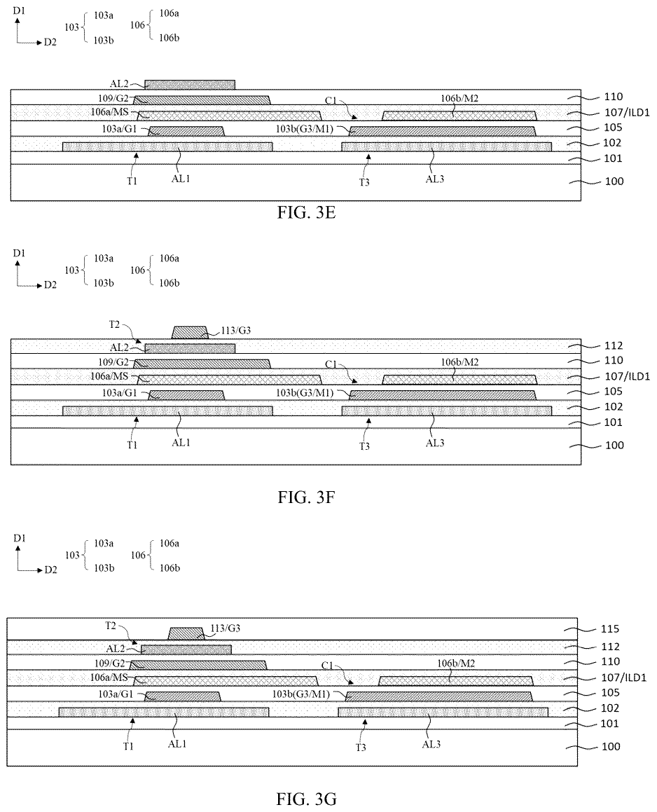

FIG. 3A to FIG. 3J illustrate schematic cross-sectional views of structures in respective process steps of a method of manufacturing an array substrate 500a according to some embodiments of the present disclosure.

Referring to FIG. 3A, in some embodiments, a base substrate 100 is provided. The base substrate 100 may be a rigid substrate and may include a material such as glass; alternatively, the base substrate 100 may be a flexible substrate and may include a material such as polyethylene terephthalate (PET), polyethylene naphthalate (PEN), polyimide (PI), or the like, and the present disclosure is not limited thereto.

A buffer layer 101 is formed on the base substrate 100. The buffer layer 101 may include an insulation material such as silicon oxide, silicon nitride, or the like, and may be formed on a side of the base substrate 100 by a deposition process such as chemical vapor deposition (CVD), for example, formed on the main surface of the base substrate 100.

The active layers AL1 and AL3 are formed on a side of the buffer layer 101 away from the base substrate 100. In some embodiments, the active layers AL1 and AL3 include semiconductor materials such as polysilicon, for example, include low-temperature polysilicon (LTPS). The method of manufacturing the active layers AL1 and AL3 may include forming an active material layer (for example, a low-temperature polysilicon layer) on the buffer layer 101, and then performing a patterning process on the active material layer to form the active layers AL1 and AL3; and the patterning process may include photolithography and etching processes. The active layers AL1 and AL3 will be served as active layers for the thin film transistors T1 and T3, respectively.

Thereafter, the insulation layer 102 is formed on a side of the buffer layer 101 away from the base substrate 100, to cover the sidewalls of the active layers AL1 and AL3 and surfaces thereof at the side away from the buffer layer 102. In some embodiments, the insulation layer 102 may include an insulation material such as silicon oxide, silicon nitride, silicon oxynitride, or the like, or a high dielectric constant material such as hafnium oxide, and may be formed by a deposition process such as CVD. Some portions of the insulation layer 102 will be served as gate insulation layers of the thin film transistors T1 and T3, respectively.

Referring to FIG. 3B, the metal material layer 103 is formed on a side of the insulation layer 102 away from the active layers AL1 and AL3, and the buffer layer 101. The metal material layer 103 may include a metal material such as copper, aluminum, molybdenum, titanium, or the like. The metal material layer 103 may include metal layers 103a and 103b spaced apart from each other. For example, a metal material layer may be formed through a deposition process such as physical vapor deposition (PVD), and then a patterning process is performed on the metal material layer to form the metal layers 103a and 103b. At least portions of the metal layers 103a and 103b will be respectively served as the gate electrodes G1 and G3 of the thin film transistors T1 and T3, respectively, and at least a portion of the metal layer 103b will be also served as the electrode plate M1 of the capacitor C1. In some embodiments, the metal layers 103a and 103b may each be or include a gate signal line, and a portion of the gate signal line is served as a gate electrode of the corresponding thin film transistor.

Referring to FIG. 3C, the insulation layer 105 is formed on a side of the insulation layer 102 away from the buffer layer 101, to cover the sidewalls of the metal material layer 103 and the surface thereof at the side away from the insulation layer 102. The material of the insulation layer 105 may be similar to, the same as or different from the material of the insulation layer 102. For example, the insulation layer 105 may be selected from insulation materials such as silicon oxide, silicon nitride, silicon oxynitride, or high dielectric constant materials such as hafnium oxide, and may be formed by a deposition process such as CVD.

The metal material layer 106 is formed on a side of the insulation layer 105 away from the metal material layer 103. The material of the metal material layer 106 may be the same as or different from the material of the metal material layer 103. For example, the metal layer 106 may include a metal material such as copper, aluminum, molybdenum, titanium, or the like, or a metal oxide material such as indium tin oxide (ITO). It should be understood that, in the present disclosure, the “metal material layer” or “metal layer” may be or include any material layer containing an metal element, such as metal, metal alloy, metal oxide, etc. In some embodiments, the metal material layer 106 includes a metal layer 106a and a metal layer 106b that are spaced apart from each other. For example, a metal material layer may be formed on the insulation layer 105 through a deposition process such as PVD, and then a patterning process is performed on the metal material layer to form the metal layers 106a and 106b that are spaced apart from each other. In some embodiments, the metal layer 106a may be served as the metal shielding layer MS; and the metal layer 106b may be served as the electrode plate M2 of the capacitor C1, and a portion of the insulation layer 105 is located between the electrode plate M2 and the electrode plate MI to be served as an inter-electrode insulation layer of the capacitor C1.

Referring to FIG. 3D, the dielectric layer 107 is formed on a side of the insulation layer 105 away from the insulation layer 102 and the metal material layer 103, to cover the sidewalls of the metal material layer 106 and the surface thereof at the side away from the insulation layer 105. The dielectric layer 107 may include a dielectric material such as silicon oxide, silicon nitride, or the like, or a low dielectric constant material such as SOG, and may be formed through a deposition process such as CVD or a spin coating process. In some embodiments, the dielectric layer 107 is served as the interlayer dielectric structure ILD1.

Thereafter, the metal material layer 109 is formed on a side of the dielectric layer 107 away from the insulation layer 105 and the metal material layer 106. At least a portion of the metal material layer 109 will be served as the gate electrode G2 of a thin film transistor. In some embodiments, the metal material layer 109 may be or include a gate signal line, and a portion of the gate signal line is served as the gate electrode G2. The material of the metal material layer 109 may be selected from the same candidate materials as the metal material layer 103a, for example, may be selected from metal materials such as copper, aluminum, molybdenum, titanium, and the like, and may be formed through a deposition process and a patterning process.

Referring to FIG. 3E, the buffer layer 110 is formed on a side of the dielectric layer 107 away from the insulation layer 105, to cover the sidewalls of the metal material layer 109 and the surface thereof at the side away from the dielectric layer 107; and the material of the buffer layer 110 may be selected from insulation materials such as silicon oxide and silicon nitride, and the buffer layer 110 may be formed through a deposition process such as CVD.

Next, the active layer AL2 is formed on a side of the buffer layer 110 away from the metal material layer 109 and the dielectric layer 107. A portion of the buffer layer 110 is located between the active layer AL2 and the gate electrode G2, and is served as a gate insulation layer of a thin film transistor. In some embodiments, the active layer AL2 includes a material different from that of the active layers AL1 and AL3. For example, the active layer AL2 may include an oxide semiconductor material such as indium gallium zinc oxide (IGZO), but the present disclosure is not limited thereto. In some other embodiments, the second active material layer where the active layer AL2 is located and the first active material layer where the active layers AL1 and AL3 are located may also include the same type of material, for example, they may both be semiconductor materials such as low-temperature polysilicon, or both be oxide semiconductor materials such as IGZO.

Referring to FIG. 3F, the insulation layer 112 is formed on a side of the buffer layer 110 away from the dielectric layer 107 and the metal material layer 109, to cover the sidewalls of the active layer AL2 and the surface thereof at the side away from the buffer layer 110; then, the metal material layer 113 is formed on a side of the insulation layer 112 away from the buffer layer 110 and the active layer AL2. At least a portion of the metal material layer 113 is served as the gate electrode G3 of the thin film transistor T2; and a portion of the insulation layer 112 is located between the gate electrode G3 and the active layer AL2 and is served as the gate insulation layer of the thin film transistor T2. In some embodiments, the metal material layer 113 may be or include a gate signal line, and a portion of the gate signal line is served as the gate electrode G3. The material of the insulation layer 112 may be selected from the same candidate materials as the insulation layer 102/105 and the buffer layer 110, for example, may include an insulation material such as silicon oxide, silicon nitride, or the like, or a high dielectric constant material such as hafnium oxide, and may be formed by a deposition process such as CVD. The material of the metal material layer 113 may be selected from the same candidate materials as the metal material layers 103 and 109, for example, may include a metal material such as copper, aluminum, molybdenum, titanium, etc., and may be formed by a deposition process such as PVD and a patterning process.

Referring to FIG. 3G, the dielectric layer 115 is formed on a side of the insulation layer 112 away from the buffer layer 110 to cover the sidewalls of the metal material layer 113 and the surface thereof at the side away from the insulation layer 112. The dielectric layer 115 may include a dielectric material such as silicon oxide, silicon nitride, or the like, and may be formed by a deposition process such as CVD or a spin coating process.

Referring to FIG. 3H, a patterning process is performed on a plurality of dielectric/insulation layers to form a plurality of via holes in the dielectric/insulation layers to expose corresponding active material layers, metal material layers, etc. For example, a first patterning process is performed on the dielectric layer 115 to the insulation layer 102 to remove portions of the dielectric/insulation layers and form via holes VH1, VH5, VH6, and VH7. The first patterning process may include photolithography and etching processes, for example, include depositing a photoresist layer on the dielectric layer 115 and patterning the photoresist layer using a photolithography process, and then performing an etching process on the plurality of dielectric/insulation layers using the patterned photoresist layer as a mask, to form a plurality of via holes in these layers. For example, the via hole VH1 extends through the dielectric layer 115, the insulation layer 112, the buffer layer 110, the dielectric layer 107, the insulation layer 105, and a part of the insulation layer 102, and exposes a portion of the active layer AL1; the via hole VH6 extends through the dielectric layer 115, the insulation layer 112, the buffer layer 110, the dielectric layer 107, and a part of the insulation layer 105, and exposes a portion of the metal layer 103b; the via hole VH5 and the via hole VH7 respectively extend through the dielectric layer 115, the insulation layer 112, the buffer layer 110, and a part of the dielectric layer 107, and expose portions of metal layers 106a and 106b.

Referring to FIG. 3I, a second patterning process is performed on the plurality of dielectric/insulation layers to form via holes VH2, VH3, and VH4. The via hole VH2 extends through the dielectric layer 115 and a part of the insulation layer 112 and exposes a portion of the active layer AL2; the via hole VH3 extends through a part of the dielectric layer 115 and exposes a portion of the metal layer 113; the via hole VH4 extends through the dielectric layer 115, the insulation layer 112, and a part of the buffer layer 110, and exposes a portion of the metal material layer 109. In the above-mentioned patterning process, the etching process has a high etching selectivity ratio of dielectric/insulation materials to active/metal materials, and the corresponding active layer/metal layer is served as an etching stop layer in the etching process. It should be understood that the above-mentioned plurality of via holes VH1-VH7 are formed through two patterning processes, but the present disclosure is not limited thereto. In alternative embodiments, a plurality of via holes may be formed through one patterning process or more than two patterning processes, and the number of via holes is not limited to that shown in the figure.

Referring to FIG. 3J, the metal layer 116 is formed on the dielectric layer 115. The metal layer 116 includes a plurality of conductive connectors and extends into the plurality of via holes VH1-VH7 to be electrically connected to the corresponding active layer or metal layer. The method of manufacturing the metal layer 116 may include, for example: depositing a metal material layer on the dielectric layer 115, wherein the metal material layer extends on a side of the dielectric layer 115 away from the insulation layer 112, and fills into the via holes VH1-VH7 to be connected to the corresponding active layer or metal layer; thereafter, performing a patterning process on the metal material layer to form the source/drain electrode SD1a, the source/drain electrode SD2a, the conductive connector GC, the direct current signal layer DS, and the conductive connectors Ct1 and Ct2, which are separated from each other. Each of the source/drain electrode SD1a, the source/drain electrode SD2a, the conductive connector GC, the direct current signal layer DS, and the conductive connectors Ct1 and Ct2 includes a conductive via v1-v7 located in the corresponding via hole VH1-VH7, and is electrically connected to a corresponding active layer or metal layer through the conductive via.

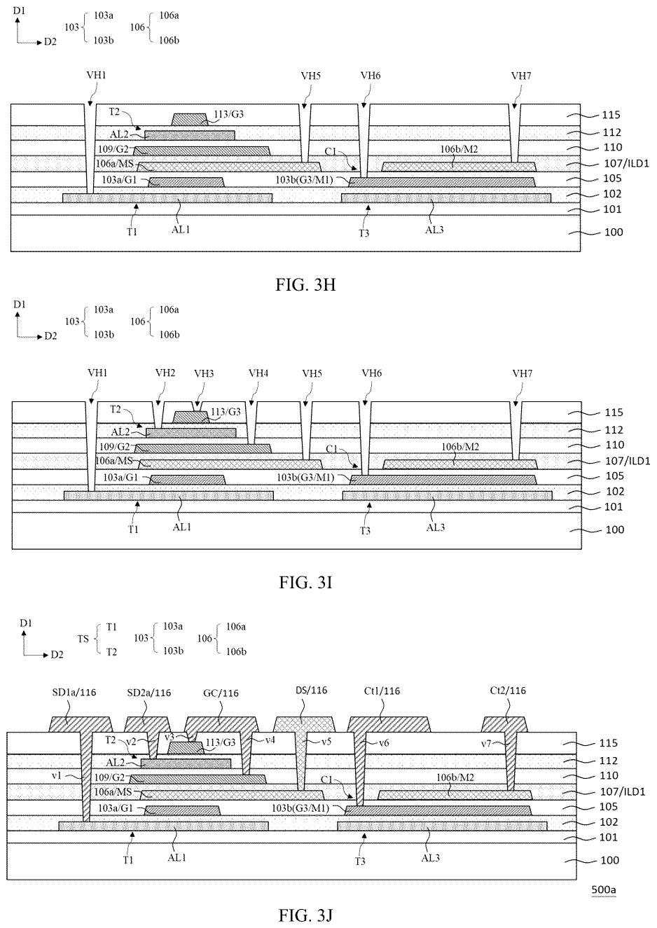

FIG. 4 illustrates a schematic cross-sectional view of an array substrate 500b according to some other embodiments of the present disclosure. The structure of the array substrate 500b is similar to that of the array substrate 500a, and the difference lies in that: in the array substrate 500b, the thin film transistor T2 does not have a dual-gate structure and does not include a bottom gate electrode.

Referring to FIG. 4, in some embodiments, the thin film transistor T2 includes a gate electrode G3, an active layer AL2, and a gate insulation layer located between the gate electrode G3 and the active layer AL2. The thin film transistor T2 may have a top gate structure, that is, the gate electrode G3 is located on a side of the active layer AL2 away from the base substrate 100. In this embodiment, because the bottom gate electrode G2 shown in FIG. 2 is omitted, the conductive via v4 is correspondingly omitted, and the conductive connector GC is connected to the gate electrode G3 through only the conductive via v3. The metal shielding layer MS and the gate electrode G3 are located on opposite two sides of the active layer AL2, that is, the gate electrode G3 is located on a side of the active layer AL2 away from the metal shielding layer MS. The active layer AL2 is located between the gate electrode G3 and the metal shielding layer MS. In some embodiments, dielectric materials such as the buffer layer 110 and the dielectric layer 107 are disposed between the active layer AL2 and the metal shielding layer MS, and there may be no other metal material layers disposed between the metal shielding layer 106a and the active layer AL2. The active layer AL2 at least partially overlaps with the metal shielding layer MS in the direction perpendicular to the main surface of the base substrate 100. In some embodiments, the orthographic projection of the active layer AL2 on the base substrate 100 is within a range of the orthographic projection of the metal shielding layer 106a on the base substrate 100; alternatively, at least the orthographic projection of the channel region of the active layer AL2 on the base substrate 100 is within a range of the orthographic projection of the metal shielding layer 106a on the base substrate 100.

Similar to the previous embodiment, the metal shielding layer MS is connected to a direct current signal terminal and is configured to shield signal crosstalk between the thin film transistors T1 and T2, for example, shield signal crosstalk between their gate electrodes G1 and G3. In some embodiments, the metal shielding layer MS is further configured to control or adjust the threshold voltage of the thin film transistor T2 by selecting the type of the direct current signal terminal to which the metal shielding layer MS is connected. For example, when the metal shielding layer MS is connected to a negative voltage, the threshold voltage of the thin film transistor T2 is positively biased; and when the metal shielding layer MS is connected to a positive voltage, the threshold voltage of the thin film transistor T2 is negatively biased. Disposing the active layer AL2 and the metal shielding layer MS to overlap with each other can facilitate the metal shielding layer MS to control the channel region of the active layer AL2, thereby achieving control of the threshold voltage of the thin film transistor T2. It should be noted that, the metal shielding layer MS is not electrically connected to the gate electrode G3, and the conductive connector GC connected to the gate electrode G3, and the direct current signal layer DS connected to the metal shielding layer MS are electrically isolated from each other.

The forming process of the array substrate 500b is similar to the forming process of the array substrate 500a shown in FIG. 3A to FIG. 3J, except that the steps of forming the metal material layer 109/gate electrode G2 in FIG. 3D are omitted, and the via hole VH4 and the conductive via v4 are not formed in the steps of FIG. 3I to FIG. 3J, the remaining steps are similar to the previous embodiment and will not be described again here.

FIG. 5 illustrates a schematic cross-sectional view of an array substrate 500c according to some other embodiments of the present disclosure. The array substrate 500c is similar to the array substrate 500b, except that the metal shielding layer MS and the electrode plate M2 of the capacitor C1 share the same one metal layer 106′.

Referring to FIG. 5, in some embodiments, the second metal material layer includes a metal layer 106′, and the metal layer 106′ continuously extends from a region where the thin film transistor group TS is located to a region where the capacitor C1 is located. For example, the array substrate 500c includes a first region R1 and a second region R2 disposed side by side in a direction parallel to the main surface of the base substrate 100. The thin film transistor group TS may be located in the first region R1, and the capacitor C1 may be located in the second region R2. The metal layer 106′ may continuously extend from a position in the first region R1 overlapping with the thin film transistors T1 and T2 to a position in the second region R2 overlapping with the metal layer 103b, and is also used as the metal shielding layer MS of the signal shielding structure S1 and the electrode plate M2 of the capacitor C1. In other words, the metal shielding layer MS may be in the same layer as the second metal material layer. It should be noted that, the second region R2 may be any region other than the first region R1 where the thin film transistor group TS is located. The components disposed in the second region R2 are not limited to the capacitor C1, and the second region R2 may alternatively or additionally include any other suitable types of devices.

In some embodiments, the direct current signal layer DS is connected to the metal layer 106′ through the conductive via v5. The direct current signal layer DS may be or be connected to a direct current power supply voltage terminal, such as the power supply voltage VDD, but the present disclosure is not limited thereto. In other words, the metal shielding layer MS and the electrode plate M2 are physically and electrically connected to each other, and connected to the same one direct current signal terminal through the same one conductive via v5. Compared with the array substrate 500b, the conductive connector Ct2 including the conductive via v7 (FIG. 4) may be omitted in the array substrate 500c. The manufacturing process of the array substrate 500c is similar to the array substrate 500b, and the difference lies in that: in this embodiment, in the patterning process of forming the metal layers 106a and 106b shown in FIG. 3C, the metal material layer is patterned into a continuous metal layer 106′, and the conductive connector Ct2 including the conductive via v7 is not formed in the steps of FIG. 3H to FIG. 3J. In this way, the mask pattern used in the process of forming the metal layer 106′ may be simplified, and the number of via holes formed in the processes of FIG. 3H to FIG. 3J may be reduced, thus simplifying the process.

FIG. 6 illustrates a schematic cross-sectional view of an array substrate 500d according to some other embodiments of the present disclosure. The array substrate 500d is similar to the array substrate 500b in the previous embodiment, and the difference lies in that, in addition to the metal shielding layer, the signal shielding structure of the array substrate 500d may further include a dielectric shielding unit to further improve the signal shielding capability of the signal shielding structure.

Referring to FIG. 6, in some embodiments, in the array substrate 500d, the signal shielding structure S2 may include a metal shielding layer MS and a dielectric shielding unit DS. The dielectric shielding unit DS may be a portion of the interlayer dielectric structure ILD2. For example, the interlayer dielectric structure ILD2 is disposed between the thin film transistors T1 and T2. Specifically, the interlayer dielectric structure ILD2 may be located between the insulation layer 105 and the buffer layer 110, the metal shielding layer MS may be embedded in the interlayer dielectric structure ILD2, and a portion of the interlayer dielectric structure ILD2 is served as the dielectric shielding unit DS. For example, the interlayer dielectric structure ILD2 may include a dielectric layer 107 and a dielectric protrusion 108; the dielectric layer 107 extends in a direction parallel to the main surface of the base substrate 100, and the metal shielding layer MS is, for example, embedded in the dielectric layer 107; and the dielectric protrusion 108 may be located on a side of the dielectric layer 107 away from the thin film transistor T1. For example, the dielectric protrusion 108 protrudes from a surface of the dielectric layer 107 away from the thin film transistor T1 toward the thin film transistor T2. The dielectric protrusion 108, served as the dielectric shielding unit DS, is used as a portion of the signal shielding structure S2. For example, the dielectric shielding unit DS can shield the influence of the signal transition of the gate electrode G1 (or the gate signal line where the gate electrode is located) on the channel region of the active layer AL2.

In some embodiments, the dielectric layer 107 may be referred to as a dielectric body part of the interlayer dielectric structure ILD2. In some embodiments, the dielectric layer 107 continuously extends from the first region R1 where the thin film transistor group TS is located to a region outside the first region R1, such as the second region R2; and the dielectric protrusion 108 may be disposed in the first region R1 and does not extend into the second region R2. In some embodiments, the materials of the dielectric layer 107 and the dielectric protrusion 108 are different, and there is an obvious interface between the dielectric layer 107 and the dielectric protrusion 108, but the present disclosure is not limited thereto. The dielectric layer 107 and the dielectric protrusion 108 may also include the same material. In some embodiments, at least the dielectric protrusion 108 of the interlayer dielectric structure ILD2 is formed from a planarization material (e.g., SOG) and provide a planar surface at the side away from the dielectric layer 107.

In some embodiments, the buffer layer 110, the insulation layer 112 and the dielectric layer 115 overlying the dielectric protrusion 108 may all be conformal layers, and also have corresponding protrusions in a region directly above the dielectric protrusion 108. In some embodiments, the active layer AL2 and the gate electrode G3 of the thin film transistor T2 overlap with the dielectric shielding unit DS in the direction D1. For example, the orthographic projection of the active layer AL2 on the main surface of the base substrate 100 is within a range of the orthographic projection of the dielectric shielding unit DS on the main surface of the base substrate 100; and the orthographic projection of the gate electrode G3 on the main surface of the base substrate 100 may also be within the range of the orthographic projection of the dielectric shielding unit DS on the main surface of the base substrate 100.

In some embodiments, because the dielectric shielding unit DS is formed by a planarization material layer and has a flat surface, the buffer layer 110 formed thereon also has a flat surface, such that components such as the active layer AL2 of the thin film transistor T2 are formed on a flat surface, and have stable and reliable performance. That is, the dielectric shielding unit DS may shield the topography of the bottom structure, so that the thin film transistor T2 is formed on a flat surface, thereby improving the stability and reliability of the thin film transistor T2.

In some embodiments, the material of the dielectric shielding unit DS is a low dielectric constant dielectric material, which may be or include an organic dielectric material such as spin-on glass (SOG) or a polymer. In the present disclosure, a low dielectric constant dielectric material refers to a dielectric material with a dielectric constant less than that of silicon oxide. For example, the dielectric constant of the dielectric shielding unit DS is less than the dielectric constant of the insulation layer 102/105/112. For example, the dielectric constant of the dielectric protrusion 108 may be less than the dielectric constant of the dielectric layer 107, but the present disclosure is not limited thereto. In embodiments in which the dielectric protrusion 108 and the dielectric layer 107 include different materials, the dielectric constant of the dielectric protrusion 108 may be less than or equal to 3.5, or less than or equal to 3.1 or 3.0; the dielectric constant of the dielectric layer 107 (i.e., dielectric body part) may be, for example, in a range of 3.9 to 4.5; for example, in one example, the material of the dielectric protrusion 108 includes spin-on glass, and the material of the dielectric body part 107 includes silicon oxide. In the embodiments in which the dielectric protrusion 108 and the dielectric layer 107 include the same material, the dielectric constants of the dielectric protrusion 108 and the dielectric layer 107 may both be less than or equal to 3.5 or even less than or equal to 3.1 or 3.0, for example, both the dielectric protrusion 108 and the dielectric layer 107 may include an low dielectric constant material such as spin-on glass.

In some embodiments, the thickness of the dielectric shielding unit DS may be greater than 1 μm, and may be greater than the thickness of the dielectric layer 107. By providing the dielectric shielding unit DS with sufficient thickness and low dielectric constant between the thin film transistors T1 and T2, the parasitic capacitance between signal lines (for example, adjacent gate signal lines) of adjacent thin film transistors T1 and T2 may be reduced, thereby reducing signal crosstalk (e.g., gate signal crosstalk) between the adjacent thin film transistors T1 and T2.

In this embodiment, the metal shielding layer MS and the dielectric shielding unit DS can both have the effect of shielding signal crosstalk, and together form the signal shielding structure S2, thereby achieving double shielding of signal crosstalk between adjacent thin film transistors, and further improving the signal shielding capability of the signal shielding structure.

In some embodiments, because the portions of the buffer layer 110, the insulation layer 112, and the dielectric layer 115 directly above the dielectric shielding unit DS also have a protrusion shape, the source/drain electrode SD2a and the conductive connector GC on these layers may be located at a level height different from other components in the metal layer 116. For example, the distance from the surfaces (i.e., the top surfaces shown in the figure) of the source/drain electrode SD2a and the conductive connector GC away from the dielectric layer 115 to the main surface of the base substrate 100 is greater than the distance from the surfaces (i.e., the top surfaces shown in the figure) of the source/drain electrode SD1a, the direct current signal terminal DS, and the conductive connectors Ct1 and Ct2 away from the dielectric layer 115 to the main surface of the base substrate 100.

In some embodiments, the dielectric shielding unit DS is disposed at a position overlapping with the thin film transistors T1 and T2 in the first region R1 where the thin film transistor group TS is located, without extending to other regions (for example, the second region R2), and a plurality of conductive vias v1-v7 are disposed laterally aside the dielectric shielding unit DS in a direction (e.g., the direction D2) parallel to the main surface of the base substrate 100, and are spaced apart from the dielectric shielding unit DS. In this way, adding the dielectric shielding unit DS will not adversely affect the etching process of forming the via holes. In some embodiments, the dielectric shielding unit DS is formed on a side of the dielectric layer 107 and the insulation layer 105 away from the metal material layer 103, instead of replacing the layer where the insulation layer 105 is located with the dielectric shielding unit DS, so that the dielectric shielding unit DS is disposed without affecting the capacitance of the capacitor C1.

In some embodiments, the dielectric shielding unit DS and the metal shielding layer MS overlap with each other, for example, at least partially overlap with each other, in the direction D1 perpendicular to the main surface of the base substrate 100. In this embodiment, the dielectric shielding unit DS is located on a side of the metal shielding layer MS away from the thin film transistor T1, and the metal shielding layer MS may be located between the dielectric shielding unit DS and the gate electrode G1 of the thin film transistor T1, and is connected to the direct current signal layer DS through the conductive via v5. In some embodiments, a portion (or may be referred to as an extension part) of the metal shielding layer MS laterally extends beyond the sidewall/edge of the dielectric shielding unit DS in the direction (e.g., the direction D2) parallel to the main surface of the base substrate 100, and the extension part of the metal shielding layer MS is used for the landing of the conductive via v5. In this way, during the etching process of forming the via hole for the conductive via v5, the dielectric shielding unit DS can be bypassed, thereby preventing the setting of the dielectric shielding unit from affecting the etching process of forming the via hole.

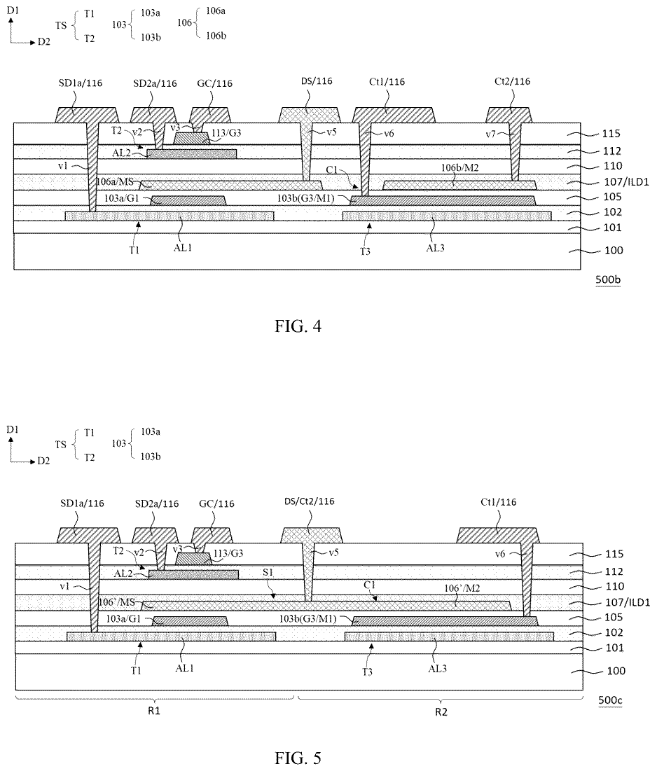

FIG. 7A to FIG. 7G illustrate a method of manufacturing an array substrate 500d according to some embodiments of the present disclosure. The manufacturing method of the array substrate 500d is similar to the previous embodiment, except that the forming process of the interlayer dielectric structure ILD2 includes forming the dielectric layer 107, and further includes forming the dielectric protrusion 108.

For example, referring to FIG. 7A, in some embodiments, processes similar to those described above with respect to FIG. 3A to FIG. 3D are performed to sequentially form the buffer layer 101, the active layers AL1 and AL3, the insulation layer 102, the metal material layer 103, the insulation layer 105, the metal material layer 106, and the dielectric layer 107 on the base substrate 100. In some embodiments, the dielectric layer 107 includes a dielectric material such as silicon oxide, and may be formed by a deposition process such as CVD.

Referring to FIG. 7B, a dielectric layer 108′ is formed on a side of the dielectric layer 107 away from the insulation layer 105. In some embodiments, the dielectric layer 107 and the dielectric layer 108′ may also be referred to as a first dielectric layer and a second dielectric layer, respectively. The dielectric layer 108′ may be a planarization dielectric layer and have a flat surface at the side away from the dielectric layer 107. In some embodiments, the dielectric layer 108′ may be or include a dielectric material such as SOG, and may be formed by a spin coating process, but the present disclosure is not limited thereto. The dielectric layer 108′ may include any dielectric material that has a low dielectric constant and can provide a flat surface. In some embodiments, the material of the dielectric layer 108′ is different from the materials of the insulation layers 102 and 105, and the dielectric constant of the dielectric layer 108′ is less than the dielectric constants of the insulation layers 102 and 105. The material of the dielectric layer 108′ may also be different from the material of the dielectric layer 107, and the dielectric constant of the dielectric layer 108′ may be less than the dielectric constant of the dielectric layer 107. Alternatively, the material of the dielectric layer 108′ may be similar to or the same as the material of the dielectric layer 107, and the dielectric constants thereof may be close to each other or substantially the same. In some embodiments, the difference in dielectric constant between the dielectric layer 108′ and the dielectric layer 107 is less than the difference in dielectric constant between the dielectric layer 108′ and the insulation layer 102 or 105. Using a dielectric material with a relatively high dielectric constant for the insulation layers 102 and 105 may be beneficial for reducing the leakage current of the thin film transistors T1 and T3 and increasing the capacitance of the capacitor C1; while using a dielectric material with a relatively low dielectric constant for the dielectric layers 107 and 108′ may be beneficial for subsequently reducing signal crosstalk between adjacent metal material layers, and improving their signal shielding capabilities.

Referring to FIG. 7B and FIG. 7C, a patterning process is performed on the dielectric layer 108′ to remove a portion of the dielectric layer 108′ and form a dielectric protrusion 108. The patterning process may include photolithography and etching processes. For example, a patterned mask layer is formed on the dielectric layer 108′. The patterned mask layer is, for example, a patterned photoresist layer formed by a photolithography process. The patterned mask layer covers the region where the dielectric protrusion 108 is to be formed and has an opening to expose other portions of the dielectric layer 108′; then, an etching process is performed on the dielectric layer 108′ using the patterned mask layer as an etching mask, to remove the portion of the dielectric layer 108′ exposed by the mask layer, thereby forming the dielectric protrusion 108 and exposing a portion of the surface of the dielectric layer 107. For example, the etching process removes the dielectric layer 108′ in the second region R2, and may also remove a portion of the dielectric layer 108′ in the first region R1. In some embodiments, the dielectric protrusion 108 and the dielectric layer 107 together constitute an interlayer dielectric structure ILD, and the dielectric protrusion 108 may be served as a dielectric shielding unit DS, the dielectric shielding unit DS and the metal shielding layer MS together constitute a signal shielding structure S2.

In this embodiment, the dielectric protrusion 108 is only formed at the position where signal shielding between adjacent thin film transistors can be achieved in the region where the thin film transistor group TS is located, without extending to other regions of the array substrate. In this way, the dielectric protrusion 108 can be disposed without affecting the subsequent etching process of forming via holes.

In some embodiments, a portion of the dielectric layer 108′ directly above the metal shielding layer MS remains to form the dielectric protrusion 108, and another portion of the dielectric layer 108′ directly above the metal shielding layer MS is removed during the etching process, so that a portion of the metal shielding layer MS extends beyond the edge of the dielectric protrusion 108 in the horizontal direction, and the portion of the metal shielding layer MS may be used for the landing of a subsequently formed conductive via.

Referring to FIG. 7D, a buffer layer 110 is formed on a side of the interlayer dielectric structure ILD away from the insulation layer 105 and the thin film transistor T1. The buffer layer 110 may conformally extend along the surfaces of the dielectric layer 107 and the dielectric protrusion 108. Thereafter, an active layer AL2 is formed on a side of the buffer layer 110 away from the dielectric protrusion 108. In some embodiments, the active layer AL2 is formed directly above the dielectric protrusion 108, and the active layer AL2 may be formed within a region where the dielectric protrusion 108 is located. Because the dielectric protrusion 108 is formed by a planarization material and has a flat surface, the buffer layer 110 formed thereon also has a flat surface. Therefore, through forming the active layer AL2 within the region where the dielectric protrusion 108 is located, the entire active layer AL2 can be formed on a flat surface, which can avoid problems such as instability caused by the active layer AL2 being formed on an uneven surface, thereby improving the reliability of the active layer AL2 and the thin film transistor including the same.

Referring to FIG. 7E, an insulation layer 112 is formed on a side of the buffer layer 110 away from the interlayer dielectric structure ILD to cover the sidewalls of the active layer AL2 and the surface thereof at the side away from the buffer layer 110. The insulation layer 112 may also have a topography similar to that of the interlayer dielectric structure ILD. Thereafter, a metal material layer 113 is formed on a side of the insulation layer 112 away from the active layer AL2. At least a portion of the metal material layer 113 is served as the gate electrode G3 of the thin film transistor T2.

Referring to FIG. 7F and FIG. 7G, a dielectric layer 115 is formed on a side of the insulation layer 112 away from the buffer layer 110 to cover the sidewalls of the metal material layer 113 and the surface thereof at the side away from the insulation layer 112. Then, one or more patterning processes are performed on dielectric/insulation material layers such as a plurality of dielectric layers, insulation layers, the buffer layer, etc., so as to form a plurality of via holes VH1, VH2, VH3, VH5, VH6, and VH7 in these dielectric/insulation material layers. The one or more patterning processes include an etching process, and are similar to the processes described with respect to FIG. 3H and FIG. 3I in the previous embodiments, and will not be described again here.

In some embodiments, because the dielectric protrusion 108 is only formed at the position between adjacent thin film transistors in the first region where the thin film transistor group is located, and does not extend to other regions, during the etching process for forming the via holes VH1-VH7, the plurality of via holes are formed laterally aside or directly above the dielectric protrusion 108, and do not penetrate through the dielectric protrusion 108. As a result, in this embodiment, the number and/or thickness of material layers that need to be removed during the etching process for forming via holes is substantially the same as the number and/or thickness of material layers that need to be removed during the etching process (FIG. 3H to FIG. 3I) for forming via holes in the above embodiment without the dielectric protrusion 108. That is, the arrangement of the dielectric protrusion 108 does not affect the etching process for forming the via holes.

In this embodiment, a portion (or may be referred to as an extension part) of the metal shielding layer MS laterally extends beyond the edge of the dielectric shielding unit DS, and the via hole VH5 may be formed above the extension part of the metal shielding layer MS, and exposes a portion of the extension part of the metal shielding layer MS. That is, the via hole VH5 bypasses the region where the dielectric shielding unit DS is located and does not penetrate through the dielectric shielding unit DS, thus avoiding the arrangement of the dielectric shielding unit DS from affecting the etching process for forming the via holes.

Referring to FIG. 7H, next, a metal layer 116 is formed on the dielectric layer 115, and the metal layer 116 includes source/drain electrodes SD1a and SD2a, conductive connectors GC, Ct1, and Ct2, and a direct current signal layer DS. In some embodiments, because the active layer AL2 and the gate electrode G3 of the thin film transistor T2 are formed above the dielectric protrusion 108, the source/drain electrode SD2a connected to the active layer AL2 and the conductive connector GC connected to the gate electrode G3 are located at a level height higher than other portions of the metal layer 116. Herein, the level height at which a component is located refers to the height thereof in the direction D1 relative to the main surface of the base substrate 100. That is, the distance from top surfaces of the source/drain electrode SD2a and the conductive connector GC to the main surface of the base substrate 100 is greater than the distance from top surfaces of other portions of the metal layer 116 (e.g., the direct current signal layer DS) to the main surface of the base substrate 100.

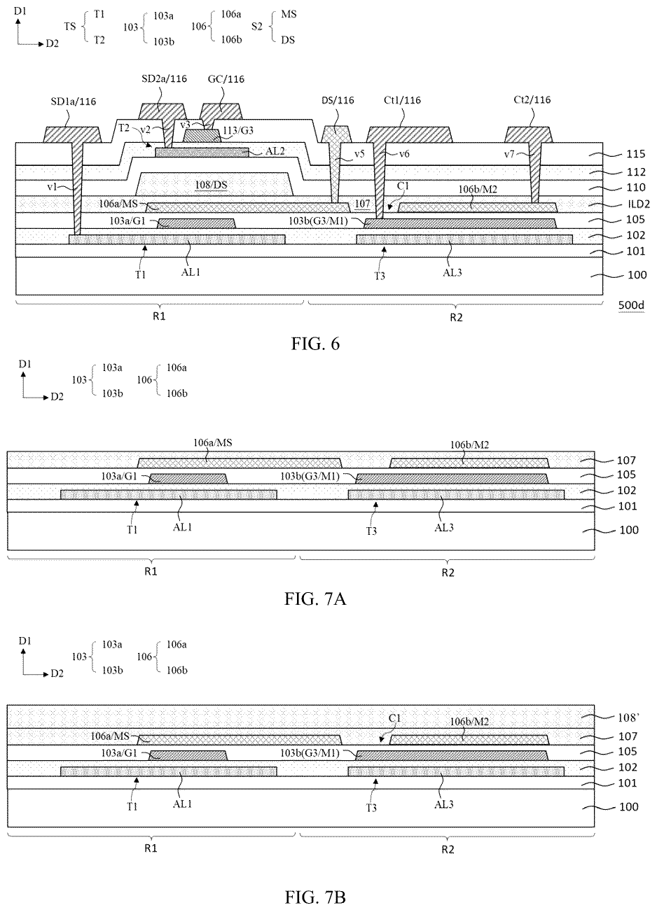

FIG. 8 illustrates a schematic cross-sectional view of an array substrate 500e according to some other embodiments of the present disclosure. The array substrate 500e is similar to the array substrate 500d, except that the positional relationship between the dielectric shielding unit DS and the metal shielding layer MS is different.

Referring to FIG. 8, in some embodiments, the metal shielding layer MS is located on a side of the dielectric shielding unit DS away from the thin film transistor T1 and close to the thin film transistor T2. For example, the metal shielding layer MS may be located between the dielectric shielding unit DS and the active layer AL2 of the thin film transistor T2. For example, the metal shielding layer MS is embedded in the buffer layer 110, and a portion of the buffer layer 110 is located between the metal shielding layer MS and the active layer AL2 to separate the metal shielding layer MS and the active layer AL2. The orthographic projection of the metal shielding layer MS on the main surface of the base substrate 100 overlaps with, for example, partially or completely overlaps with, the orthographic projection of the dielectric shielding unit DS on the main surface of the base substrate 100.

In some embodiments, the metal shielding layer MS is located on a surface (i.e., the top surface shown in the figure) of the dielectric shielding unit DS at a side close to the thin film transistor T2, and is in direct contact with the surface of the dielectric shielding unit DS. The metal shielding layer MS is connected to the direct current signal layer DS through the conductive via v5. In this embodiment, because the metal shielding layer MS is disposed above the dielectric shielding unit DS, it is unnecessary to consider the influence of the dielectric shielding unit DS during the etching process for forming the conductive via v5. Therefore, the metal shielding layer MS does not need to extend laterally beyond the edge of the dielectric shielding unit DS. In some embodiments, the orthographic projection of the metal shielding layer MS on the main surface of the base substrate 100 may be within a range of the orthographic projection of the dielectric shielding unit DS on the main surface of the base substrate 100, but the present disclosure is not limited thereto.

In this embodiment, the metal shielding layer MS and the electrode plate M2 of the capacitor C1 are disposed in different layers. For example, the electrode plate M2 is disposed in the second metal material layer where the metal layer 106b is located, while the metal shielding layer MS may be disposed in the third metal material layer 109′. The third metal material layer 109′ may also be referred to as an additional metal layer.

In this embodiment, the metal shielding layer MS is connected to a direct current signal terminal, and is not connected to the conductive connector GC, and therefore is not connected to the gate electrode G3. In addition, similar to the array substrate 500b, the threshold voltage of the thin film transistor T2 may be controlled or adjusted by selecting the type of the direct current signal terminal connected to the metal shielding layer MS. Moreover, in this embodiment, the metal shielding layer MS is closer to the active layer AL2, which can more favorably facilitate the control of the threshold voltage of the thin film transistor T2 through the metal shielding layer MS.

FIG. 9 illustrates a schematic cross-sectional view of an array substrate 500f according to some other embodiments of the present disclosure. The array substrate 500f is similar to the array substrate 500e, except that the metal material layer 109′ is connected to the gate electrode G3 and is served as the bottom gate electrode of the thin film transistor T2.

Referring to FIG. 9, in some embodiments, the metal material layer 109′ is connected to the conductive connector GC through the conductive via v5, and is further electrically connected to the gate electrode G3 (i.e., top gate electrode) through the conductive connector GC. At least a portion of the metal material layer 109′ is served as the bottom gate electrode G2 of the thin film transistor T2. For example, the metal material layer 109′ may be or include a gate signal line, and a portion of the gate signal line is served as the bottom gate electrode G2 of the thin film transistor T2. In this embodiment, the signal shielding structure S3 only includes the dielectric shielding unit DS and does not include a metal shielding layer. Because the dielectric shielding unit DS has the characteristics of low dielectric constant and large thickness, only disposing the dielectric shielding unit DS can effectively shield the signal crosstalk between the thin film transistors T1 and T2, and the metal shielding layer can thus be omitted. The metal material layer 109′ is served as the bottom gate electrode G2 of the thin film transistor T2, that is, the thin film transistor T2 has a dual-gate structure, so that the gate electrodes G2 and G3 may jointly control the channel region of the active layer AL2 more stably.

FIG. 10 illustrates a schematic cross-sectional view of an array substrate 500g according to some other embodiments of the present disclosure. The array substrate 500g is similar to the array substrate 500d, except that the interlayer dielectric structure ILD3 of the array substrate 500g is integrally formed.

Referring to FIG. 10, in some embodiments, the interlayer dielectric structure ILD includes a dielectric body part 108a and a dielectric protrusion 108b, and positions of the dielectric body part 108a and the dielectric protrusion 108b are similar to positions of the dielectric layer 107 and the dielectric protrusion 108 in the previous embodiment. For example, the dielectric body part 108b extends in the direction (e.g., the direction D2) parallel to the main surface of the base substrate 100, and may extend from the first region R1 where the thin film transistor group TS is located to the second region R2 where the capacitor C1 is located. The dielectric protrusion 108a is located in the first region R1 and between adjacent thin film transistors T1 and T2 in the thin film transistor group TS, served as a dielectric shielding unit DS and used as at least part of the signal shielding structure. The dielectric protrusion 108a protrudes toward the thin film transistor T2 from a surface (i.e., the top surface shown in the figure) of the dielectric body part 108b at a side away from the insulation layer 105 and the thin film transistor T1.

In some embodiments, the dielectric body part 108a and the dielectric protrusion 108b of the interlayer dielectric structure ILD are integrally formed, that is, the dielectric body part 108a and the dielectric protrusion 108b include the same material, and there is no interface between the dielectric body part 108a and the dielectric protrusion 108b. In some embodiments, the material of the interlayer dielectric structure ILD is substantially the same as the material of the dielectric protrusion 108 in the previous embodiments, for example, is a dielectric material with low dielectric constant such as SOG. In some embodiments, the dielectric constant of the interlayer dielectric structure ILD may be less than the dielectric constant of the insulation layer 102/105/112.

In some embodiments, the dielectric protrusion 108b of the interlayer dielectric structure ILD is served as the dielectric shielding unit DS, and the dielectric shielding unit DS and the metal shielding layer MS together constitute the signal shielding structure S2, so as to be used to shield the signal crosstalk between the thin film transistors T1 and T2. In some embodiments, the metal shielding layer MS is embedded in the interlayer dielectric structure ILD. For example, the metal shielding layer MS is embedded in the dielectric body part 108a and overlaps with (e.g., partially overlap with) the dielectric protrusion 108b in the direction D1. Similar to the previous embodiment, a portion of the metal shielding layer MS laterally extends beyond the edge of the dielectric protrusion 108b in a direction (e.g., the direction D2) parallel to the main surface of the base substrate 100, so as to be used for the landing of the conductive via v5. In some embodiments, the thickness of the dielectric body part 108a is greater than the thickness of the metal material layer 106 where the metal shielding layer MS is located, so that the dielectric body part 108a covers the surface (i.e., top surface shown in the figure) of the metal material layer 106 at the side away from the insulation layer 105. Other structural features of the array substrate 500g are similar to those of the array substrate 500d and will not be described again here.

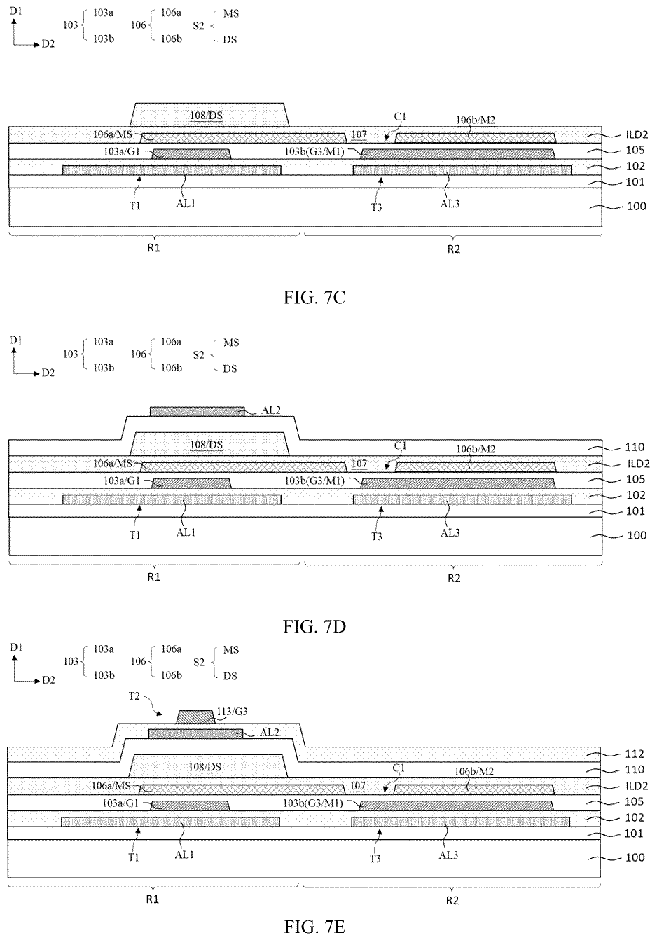

FIG. 11A to FIG. 11C illustrate schematic cross-sectional views of structures in respective process steps of a method of manufacturing an array substrate 500g according to some embodiments of the present disclosure.

Referring to FIG. 11A, process steps similar to those shown in FIG. 3A to FIG. 3C are performed to form a buffer layer 101, active layers AL1 and AL3, an insulation layer 102, a metal material layer 103, an insulation layer 105, and a metal material layer 106 on the base substrate 100. Next, a dielectric layer 108″ is formed on a side of the insulation layer 105 away from the insulation layer 102 and the metal material layer 103, so as to cover the sidewalls of the metal material layer 106 and the surface thereof at the side away from the insulation layer 105. The material and the manufacturing method of the dielectric layer 108″ are similar to the material and manufacturing method of the dielectric layer 108′ formed in the steps of FIG. 7B in the previous embodiment. For example, the dielectric layer 108″ may include a dielectric material with a low dielectric constant such as spin-on glass (SOG), and may be formed by a spin coating process. Compared with the process steps of firstly forming the dielectric layer 107 and then forming the dielectric layer 108′ in the method of manufacturing the array substrate 500d in the previous embodiment, in this embodiment, the step of forming the dielectric layer 107 is omitted, while the dielectric layer 108″ is directly formed to the required thickness of the subsequent dielectric protrusion after forming the metal material layer 106. For example, the thickness of the dielectric layer 108″ in this embodiment may be substantially equal to the sum of the thicknesses of the dielectric layer 107 and the dielectric layer 108′ shown in FIG. 7B in the previous embodiment.

Referring to FIG. 11A and FIG. 11B, a patterning process is then performed on the dielectric layer 108″ to remove a portion of the dielectric layer 108″ and form the interlayer dielectric structure ILD3 including the dielectric body part 108a and the dielectric protrusion 108b. In some embodiments, the patterning process may include the following process steps: forming a patterned mask layer on the dielectric layer 108″, in which the patterned mask layer may be or include a patterned photoresist layer; the patterned mask layer covers a portion (e.g., a first portion) of the dielectric layer 108″ located in the first region R1 where the dielectric protrusion 108b is to be formed, and exposes other portions of the dielectric layer 108″ (e.g., a second portion, which may include the dielectric layer 108″ in the second region and may also include a portion of the dielectric layer 108″ in the first region R1); using the patterned mask layer as an etching mask to perform an etching process on the dielectric layer 108″, so as to remove a portion of the dielectric layer 108″ exposed by the patterned mask layer; the etching process reduces the thickness of the second portion of the dielectric layer 108″, without completely removing the second portion of the dielectric layer 108″, thus forming a thinner dielectric body part 108a and a thicker dielectric protrusion 108b. That is, the thickness of the dielectric protrusion 108b is greater than the thickness of the dielectric body part 108a. In some embodiments, the removal amount of the dielectric layer 108″ may be controlled by controlling the etching time, thereby controlling the thickness of the dielectric body part 108a. For example, the thickness of the dielectric body part 108a is at least greater than the thickness of the metal material layer 106, so that the dielectric body part 108a can cover the sidewalls of the metal material layer 106 and the surface thereof at the side away from the insulation layer 105. In some embodiments, the thickness of dielectric body part 108a may be approximately equal to the thickness of the dielectric layer 107 in previous embodiment. The dielectric protrusion 108b protrudes upward from the top surface of the dielectric body part 108a and away from the base substrate 100 and the thin film transistor T1, and is served as a dielectric shielding unit, and is subsequently served as a portion of the signal shielding structure.

Referring to FIG. 11B and FIG. 11C, process steps similar to those shown in FIG. 7D to FIG. 7H are then performed to form components such as a buffer layer 110, an active layer AL2, an insulation layer 112, a metal material layer 113, a dielectric layer 115, and a metal layer 116 on the interlayer dielectric structure ILD3. The manufacturing method of these material layers is substantially the same as that of the previous embodiment, and will not be described again here.

In this embodiment, the array substrate 500g replaces the interlayer dielectric structure ILD2 including the dielectric layer 107 and the dielectric protrusion 108 with the integrally formed interlayer dielectric structure ILD3 based on the array substrate 500d. It should be understood that, this embodiment may also be applied to the array substrates 500e and 500f to replace the interlayer dielectric structures in the array substrates 500e and 500f with the integrally formed interlayer dielectric structure ILD3.

In this embodiment, after the metal layer 106 is formed, the interlayer dielectric structure is directly formed with a dielectric shielding material, thereby omitting the step of forming the dielectric layer 107 and simplifying the manufacturing process. On the other hand, the interlayer dielectric structure all uses a dielectric material with low dielectric constant, which can further improve the signal shielding capability of the portion of the interlayer dielectric structure between the thin film transistors T1 and T2.

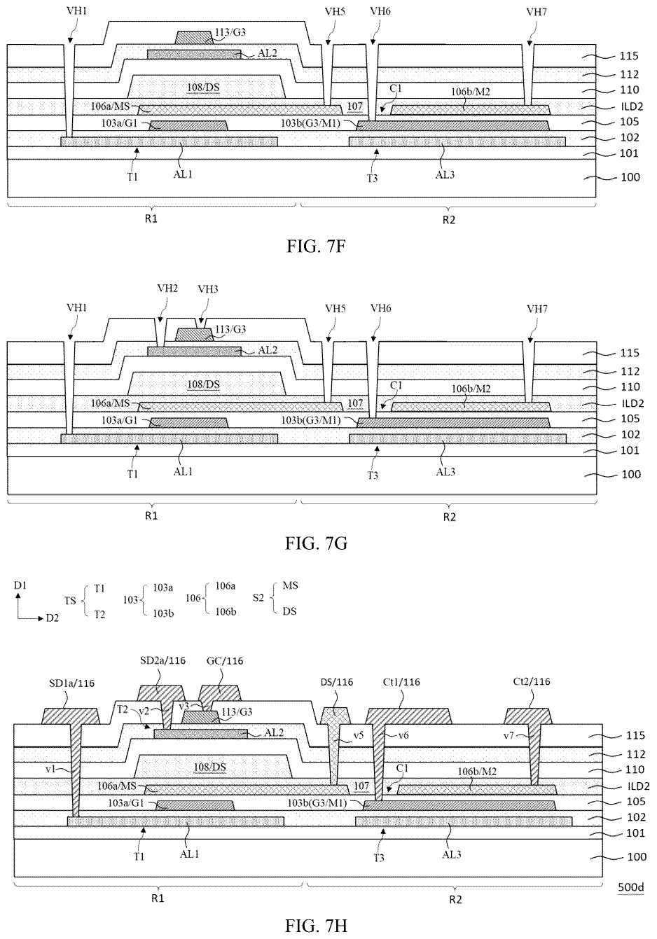

FIG. 12 and FIG. 13 illustrate schematic cross-sectional views of array substrates 500h and 500i according to some other embodiments of the present disclosure.

Referring to FIG. 12 and FIG. 13, the array substrates 500h and 500i are similar to the array substrates 500d (FIGS. 6) and 500g (FIG. 10) respectively, except that the metal shielding layer MS is omitted in the array substrates 500h and 500i, and the conductive via v5 and a part of the metal layer 116 connected thereto is omitted accordingly. The array substrates 500h and 500i respectively adopt the dielectric protrusions 108 and 108b of the interlayer dielectric structures ILD2 and ILD3 as the dielectric shielding units DS. In these embodiment, the signal shielding structure S3 may only include the dielectric shielding unit DS. Because the dielectric shielding unit DS has a low dielectric constant and sufficient thickness, the dielectric shielding unit DS alone can have good signal shielding capability, and the metal shielding layer may be omitted. In addition, because the dielectric shielding unit DS is formed by a planarization material, the dielectric shielding unit DS can not only shield the electrical signals of adjacent thin film transistors, but may also shield the topography of the material layer underlying thereof, thereby providing a flat surface for components formed thereon, thereby ensuring or improve device characteristics such as the stability of the thin film transistor T2 formed thereon. In some embodiments, the thin film transistor T2 may have good characteristics without disposing a bottom gate electrode.

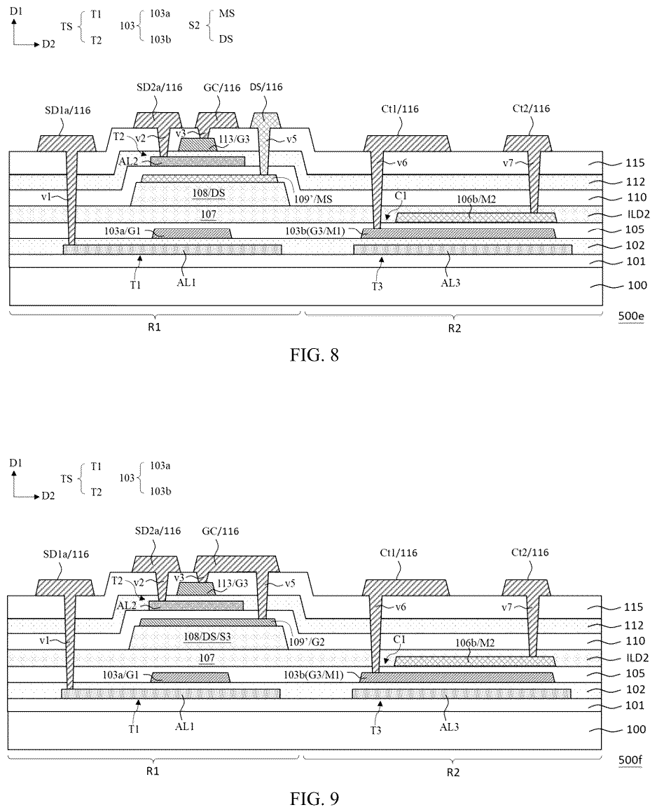

FIG. 14 illustrates a schematic block diagram of an array substrate 500 according to some embodiments of the present disclosure. The array substrate 500 may be any one of the above-described array substrates 500a-500i.

Referring to FIG. 14, in some embodiments, the array substrate 500 includes a plurality of sub-pixel driving circuits PC, for example, arranged in an array. Each sub-pixel driving circuit PC may be constituted by a plurality of thin film transistors and capacitors. In some embodiments, the thin film transistors T1 and T2 in the thin film transistor group TS of each of the array substrates 500a-500i are included in the same sub-pixel driving circuit PC. In some embodiments, one or more sub-pixel driving circuits PC are provided with thin film transistors that are stacked, for example, a thin film transistor group TS at least including the thin film transistors T1 and T2.

In some embodiments, the array substrate 500 may include a plurality of thin film transistor groups TS arranged in an array, and each thin film transistor group TS is configured to be formed in one sub-pixel driving circuit. Each thin film transistor group TS may include one or more groups of thin film transistors that are stacked. For example, the thin film transistor group TS may include a plurality of thin film transistor sub-groups, and the plurality of thin film transistor sub-groups may be arranged side by side and spaced apart from each other in a direction parallel to the main surface of the base substrate, in which each thin film transistor sub-group includes a plurality of thin film transistors that are stacked in a direction perpendicular to the main surface of the base substrate. For example, as shown in FIG. 14, the thin film transistor group TS may include a first thin film transistor sub-group constituted by a first thin film transistor T1 and a second thin film transistor T2, and a second thin film transistor sub-group constituted by a third thin film transistor T3A and a fourth thin film transistor T4A. It should be noted that, a signal shielding structure is disposed between adjacent thin film transistors that are stacked in each thin film transistor sub-group to shield signal crosstalk between adjacent thin film transistors. For example, an additional signal shielding structure is disposed between the third thin film transistor T3A and the fourth thin film transistor T4A. The additional signal shielding structure may be any one of the above-mentioned signal shielding structures, and the structural and positional relationship between the third thin film transistor T3A, the fourth thin film transistor T4A, and the additional signal shielding structure are similar to those described previously with respect to the first thin film transistor T1, the second thin film transistor T2, and the signal shielding structure, which will not be described again. It should be understood that, the number of thin film transistors included in the thin film transistor group TS in each sub-pixel driving circuit PC shown in the figure is only for illustration, and the present disclosure is not limited thereto. The numbers of thin film transistors included in the thin film transistor groups TS in different sub-pixel driving circuits PC may be the same or different from each other.

The array substrate 500 of the present disclosure may be applied to various display devices, such as LED display devices, OLED display devices, etc. In these display devices, the sub-pixel driving circuit of the array substrate is used to drive the light-emitting device to emit light.

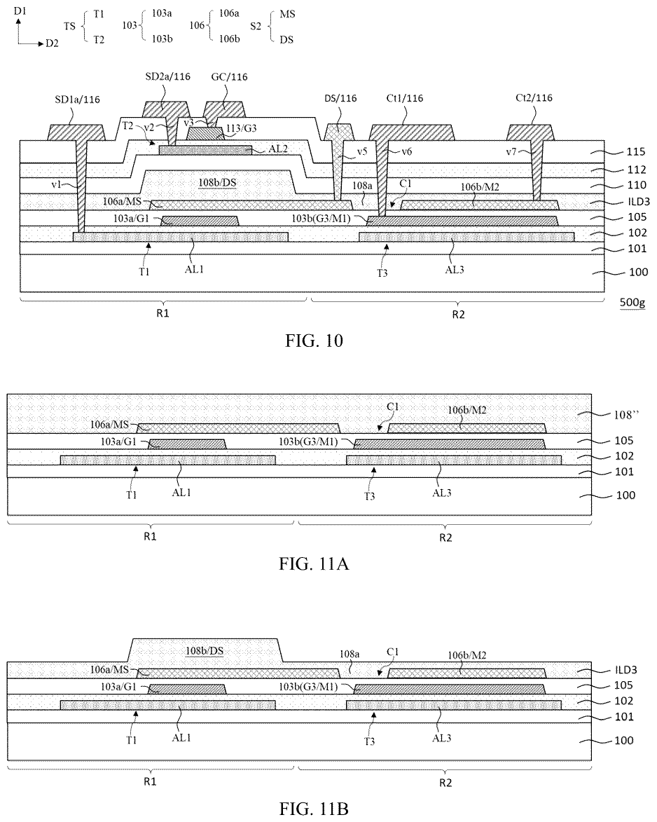

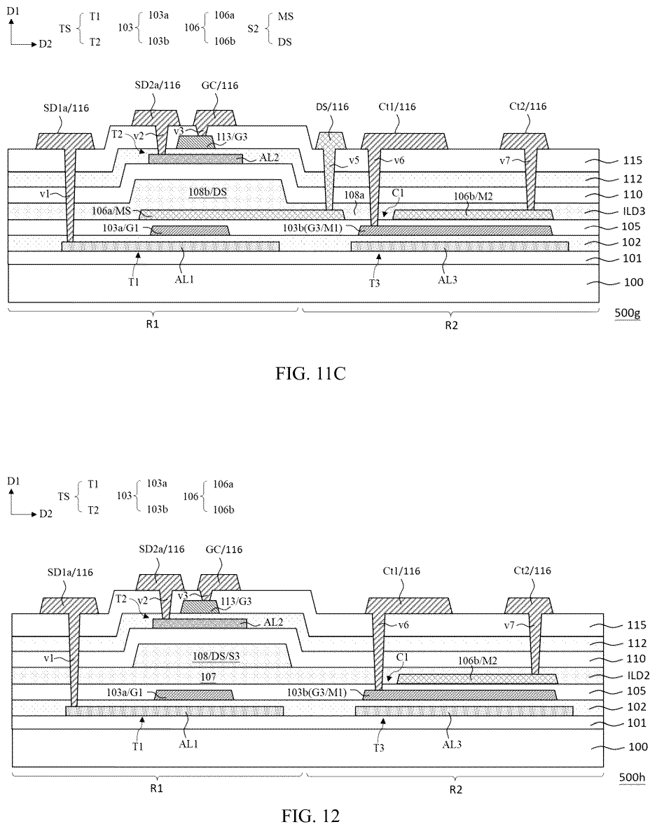

FIG. 15A illustrates a schematic block diagram of a display device 600 according to some embodiments of the present disclosure.

Referring to FIG. 15A, in some embodiments, the display device 600 may be a light-emitting diode (LED) display device, such as a micro light-emitting diode (micro-LED) display device, a sub-millimeter light-emitting diode (Mini-LED) display device, etc. The display device 600 may include an array substrate 500 and a plurality of light-emitting diode chips LC. The array substrate 500 may be selected from any of the array substrates 500a to 500i described in the previous embodiments. The light-emitting diode chip LC may be an inorganic light-emitting diode chip such as a micro-LED chip, a Mini-LED chip, etc. Each LED chip PC may be served as a sub-pixel of the display device 600.

The array substrate 500 and the plurality of light-emitting diode chips LC are electrically connected to each other. In this embodiment, the array substrate 500 is served as a driving substrate (or may also be referred to as a driving backplane) of the display device 600, and is used to drive a plurality of light-emitting diode chips PC to emit light. For example, the array substrate 500 may include a plurality of sub-pixel driving circuits PC, and each sub-pixel driving circuit PC may be connected to a corresponding one light-emitting diode chip LC for driving a corresponding light-emitting diode chip LC to emit light.

In some embodiments, the sub-pixel driving circuit PC includes a plurality of thin film transistors and capacitors, and some of the plurality of thin film transistors are stacked on each other as a thin film transistor group, thereby reducing the pixel size and improving the resolution of the display device. On the other hand, in the embodiments of the present disclosure, a signal shielding structure is disposed between stacked thin film transistors to shield signal crosstalk between adjacent thin film transistors, thereby improving the reliability and performance of the display device, and thus meeting the display function requirements of high-resolution display devices. For example, the sub-pixel driving circuit PC may include the thin film transistor group TS described with respect to the array substrate in the previous embodiments. In some embodiments, the thin film transistor groups TS in the array substrates 500a-500i are each included in a same one sub-pixel driving circuit PC.

In some embodiments, the array substrate 500 of the display device 600 has a high resolution, for example, greater than 300 pixels per inch (PPI), and may be applied to near-eye display fields such as mobile phone products, but the present disclosure is not limited thereto. The display device 600 may be applied to multiple fields, such as flat panel display; virtual reality (VR), augmented reality (AR), mixed reality (Mixed reality, MR) and other displays; as well as spatial display, flexible transparent display, wearable/implantable optoelectronic devices, optical communication/optical interconnection, medical detection, smart car lights and other fields.

FIG. 15B illustrates a schematic diagram of the sub-pixel driving circuit PC of the display device 600 according to some embodiments of the present disclosure.

Referring to FIG. 15B, in some embodiments, the sub-pixel driving circuit PC adopts an operating mode that combines pulse amplitude modulation (PAM) and pulse width modulation (PWM). For example, a PAM mode is used at low current to reduce power consumption; and a PWM mode is used at high current to reduce the instability of LED display effect under high current driving conditions.

For example, the sub-pixel driving circuit PC may include a first reset transistor T1a, a threshold compensation transistor T2a, a driving transistor T3a, a first data writing transistor T4a, a first light-emitting control transistor T5a, a second light-emitting control transistor T6a, a second reset transistor T7a, a first storage capacitor Cst1, and a light-emitting signal control sub-circuit 8. The sub-pixel driving circuit PC is used to drive the light-emitting device LD to emit light. In some embodiments, the light-emitting device LD may be the light-emitting diode chip LC shown in FIG. 15A, but the present disclosure is not limited thereto.

In some embodiments, each transistor in the pixel driving circuit PC may adopt a low-temperature polysilicon thin film transistor or an oxide thin film transistor. The active layer of the low-temperature polysilicon thin film transistor adopts a semiconductor material such as low-temperature polysilicon, and the active layer of the oxide thin film transistor adopts an oxide semiconductor material such as IGZO. Low-temperature polysilicon thin film transistors have the advantages of high mobility and fast charging, and oxide thin film transistors have the advantages of low leakage current. Through integrating low-temperature polysilicon thin film transistor(s) and oxide thin film transistor(s) on one array substrate to form a low-temperature polycrystalline oxide (LTPO) display substrate, the advantages of the both can be utilized, thereby achieving low-frequency driving, reducing power consumption, and improving display quality.

Each of the plurality of transistors of the pixel driving circuit PC includes a gate electrode, a first electrode, and a second electrode. The first electrode and the second electrode may be a source electrode and a drain electrode, respectively. It should be understood that, the source electrode and the drain electrode of a transistor are interchangeable with each other. That is, the first electrode and the second electrode may also be a drain electrode and a source electrode, respectively.

In some embodiments, as shown in FIG. 15B, the first reset transistor T1a is electrically connected to a gate electrode of the driving transistor T3a, and is configured to reset the gate electrode of the driving transistor T3a; the second reset transistor T7a is electrically connected to an anode of the light-emitting device LD, and is configured to reset the anode of the light-emitting device LD. For example, a gate electrode of the first reset transistor T1a is electrically connected to a reset control line Rst1, a first electrode of the first reset transistor T1 is electrically connected to an initial power supply terminal Vini, and a second electrode of the first reset transistor T1 is electrically connected to the gate electrode of the driving transistor T3a. A gate electrode of the second reset transistor T7a is electrically connected to a reset control line Rst2, a first electrode of the second reset transistor T7a is electrically connected to the initial power supply terminal Vini, and a second electrode of the second reset transistor T7a is electrically connected to the anode of the light-emitting device LD. A cathode of the light-emitting device LD may be connected to a first power supply voltage terminal, for example, connected to a power supply voltage VSS.

A gate electrode of the first data writing transistor T4a is connected to a first scanning signal line, and is configured to receive a first scanning signal GA1. A first electrode of the first data writing transistor T4a is connected to a data signal line, and is configured to receive a first data signal Data1, and a second electrode of the first data writing transistor T4a is connected to a first electrode of the driving transistor T3a. For example, during a data writing and compensation stage, the first data writing transistor T4a may be turned on in response to the first scanning signal GA1, write the data signal Datal to the first electrode of the driving transistor T3a, and store the data signal in a storage capacitor Cst1, so as to generate a driving current for driving the light-emitting device LD to emit light according to the data signal, for example, during a light-emitting stage.

A gate electrode of the compensation transistor T2a is electrically connected to a second scanning signal line, and is configured to receive a second scanning signal GA2. A first electrode and a second electrode of the compensation transistor T2a are electrically connected to the second electrode and the gate electrode of the driving transistor T3a, respectively. The compensation transistor T2a is configured to perform threshold compensation on the driving transistor T3a in response to the second scanning signal GA2. The first scanning signal line and the second scanning signal line may be the same or different scanning signal lines.

The first storage capacitor Cst1 includes a first electrode plate and a second electrode plate. The first electrode plate is electrically connected to a second power supply voltage terminal, for example, connected to a power supply voltage VDD. The second electrode plate is electrically connected to the gate electrode of the driving transistor T3a. The first storage capacitor Cst1 is configured to store the first data signal Datal written by the first data writing transistor T4a. For example, during the data writing and compensation stage, the compensation transistor T2a may be turned on in response to the second scanning signal GA2, so that the data signal Datal written by the first data writing transistor T4a can be stored in the first storage capacitor Cst1. For example, during both the data writing and compensation stage, the compensation transistor T2a can electrically connect the gate electrode and the second electrode of the driving transistor T3a, so that the relevant information about the threshold voltage of the driving transistor T3a can also be stored in the first storage capacitor Cst1 accordingly. Thereafter, for example, during the light-emitting stage, the data signal, and the signal related to the threshold voltage stored in the storage capacitor Cst1 can be used to control the driving transistor T3a, so that the output of the driving transistor T3a is compensated.

The first light-emitting control transistor T5a is electrically connected to the first electrode of the driving transistor T3a and the second power supply voltage terminal (e.g., the power supply voltage VDD), and is configured to apply the power supply voltage VDD to the first electrode of the driving transistor T3a in response to the light-emitting control signal EM. For example, a gate electrode of the first light-emitting control transistor T5a is electrically connected to a light-emitting control line to receive a light-emitting control signal EM. A first electrode of the first light-emitting control transistor T5a is electrically connected to the second power supply voltage terminal to receive the power supply voltage VDD, a second electrode of the first light-emitting control transistor T5a is electrically connected to the first electrode of the driving transistor T3a.

The second light-emitting control transistor T6a is electrically connected to a light-emitting signal control sub-circuit 8, the anode of the light-emitting device LD, and the second electrode of the driving transistor T3a, and is configured to apply a driving current to the light-emitting device LD under the control of the light-emitting signal control sub-circuit 8 and the driving transistor T3a. For example, a gate electrode of the second light-emitting control transistor T6a is electrically connected to the light-emitting signal control sub-circuit 8 to receive a light-emitting control signal. A first electrode of the second light-emitting control transistor T6a is electrically connected to the second electrode of the driving transistor T3a, and a second electrode of the second light-emitting control transistor T6a is electrically connected to the anode of the light-emitting device LD.

In this example, a first node N1 is a connection point of the first storage capacitor Cst1, the first reset transistor T1a, the driving transistor T3a, and the threshold compensation transistor T2a; a second node N2 is a connection point of the first light-emitting control transistor T5a, the data writing transistor T4a, and the driving transistor T3a; a third node N3 is a connection point of the driving transistor T3a, the threshold compensation transistor T2a, and the second light-emitting control transistor T6a; and a fourth node N4 is a connection point of the second light-emitting control transistor T6a, the second reset transistor T7a, and the light-emitting device LD.

In some embodiments, the light-emitting signal control sub-circuit 8 includes a first selection transistor T8a, a second selection transistor T9a, a second data writing transistor T10a, and a second storage capacitor Cst2. The second data writing transistor T10a is configured to write a second data signal Data2 to the second storage capacitor Cst2 under the control of a third scanning signal GA3. For example, a gate electrode of the second data writing transistor T10a is electrically connected to a third scanning signal line, and is configured to receive the third scanning signal GA3; a first electrode of the second data writing transistor T10a is electrically connected to a second data signal line, and is configured to receive the second data signal Data2; a second electrode of the second data writing transistor T10a is electrically connected to a first electrode of the second storage capacitor Cst2; and a second electrode of the second storage capacitor Cst2 may be electrically connected to a common voltage Vcom, or may be connected to other power supply voltage terminals.

The first selection transistor T8a and the second selection transistor T9a are each electrically connected to the second storage capacitor Cst2 and the second light-emitting control transistor T6a, and the first selection transistor T8a is configured to turn on or turn off the connection between the first light-emitting control signal EM1 and the second light-emitting control transistor T6a under the control of a first data sub-signal of the second data signal Data2; and the second selection transistor T9a is configured to turn on or turn off the connection between the second light-emitting control signal EM2 and the second light-emitting control transistor T6a under the control of a second data sub-signal of the second data signal Data2.

For example, a gate electrode of the first selection transistor Ta is electrically connected to the first electrode of the second storage capacitor Cst2; a first electrode of the first selection transistor T8a is electrically connected to a first light-emitting control signal line to be configured to receive the first light-emitting control signal EM1; and a second electrode of the first selection transistor T8a is electrically connected to the gate electrode of the second light-emitting control transistor T6a. A gate electrode of the second selection transistor T9a is electrically connected to the first electrode of the second storage capacitor Cst2; a first electrode of the second selection transistor T9a is electrically connected to a second light-emitting control signal line to be configured to receive the second light-emitting control signal EM2; and a second electrode of the second selection transistor T9a is electrically connected to the gate electrode of the second light-emitting control transistor T6a.

In some embodiments, the light-emitting signal control sub-circuit 8 is a NOT gate circuit and is configured such that when the first selection transistor T8a is turned on, the second selection transistor T9a is turned off. Alternatively, when the second selection transistor T9a is turned on, the first selection transistor T8a is turned off.

In some embodiments, the sub-pixel driving circuit PC may control the light-emitting of the light-emitting device LD during the light-emitting process in an operating mode that combines PWM and PAM. For example, PWM may be used to control the light-emitting duration of the light-emitting device LD, and PAM may be used to control the light-emitting brightness of the light-emitting device LD. For example, the PAM mode is used at a low current to reduce power consumption, and the PWM mode is used at a high current to reduce the instability of the LED display effect under high current driving conditions.

For example, the first data signal Datal is a PAM signal, and the second data signal Data2 is a PWM signal. The PAM signal is written into the driving transistor T3a through a writing circuit constituted by the first data signal transistor T4a and the compensation transistor T2a, thereby controlling the magnitude of the driving current applied to the light-emitting device LD by the driving transistor T3a, thereby achieving pulse amplitude modulation.

In some embodiments, the second data signal Data2 is a signal for pulse width modulation. For example, the second data signal Data2 may include a first data sub-signal and a second data sub-signal; the first data sub-signal is used to control the first selection transistor T8a to be turned on and control the second selection transistor T9a to be turned off; and the second data sub-signal is used to control the second selection transistor T9a to be turned on and control the first selection transistor T8a to be turned off. The pulse width of the first data sub-signal corresponds to the period during which the first light-emitting control signal EM1 turns on the second light-emitting control transistor T6a, and the pulse width of the second data sub-signal corresponds to the period during which the second light-emitting control signal EM2 turns on the second light-emitting control transistor T6a.

In some embodiments, the first light-emitting control signal EM1 is a first pulse width modulation signal, and is configured to control a first light-emitting duration of the light-emitting device LD under the driving of the first data sub-signal. The second light-emitting control signal EM2 is a second pulse width modulation signal, and is configured to control a second light-emitting duration of the light-emitting device LD under the driving of the second data sub-signal. Therefore, the light-emitting duration of the light-emitting device LD is controlled through the light-emitting signal control sub-circuit 8, thereby achieving pulse width modulation.

In some other embodiments, the light-emitting signal control sub-circuit 8 may be a dimming circuit that can realize PAM and PWM, and the second data signal Data2 may be a dimming control signal and includes a first data sub-signal and a second data sub-signal. The first light-emitting control signal EM1 may be a pulse width modulation signal, and the second light-emitting control signal EM2 may be a signal for pulse amplitude modulation. The first data sub-signal is configured to control the first selection transistor T8a to be turned on and the second selection transistor T9a to be turned off, and the first selection transistor T8a may transmit the first light-emitting control signal EM1 (i.e., pulse width modulation signal) to the second light-emitting control transistor T6a based on the first data sub-signal, thereby achieving pulse width modulation, and controlling the light-emitting duration of the light-emitting device LD. The second data sub-signal is configured to control the second selection transistor T9a to be turned on and control the first selection transistor T8a to be turned off, and the second selection transistor T9a may transmit the second light-emitting control signal EM2 to the second light-emitting control transistor T6a based on the second data sub-signal, thereby achieving pulse amplitude modulation, and controlling the light-emitting brightness of the light-emitting device LD.

In some embodiments, the thin film transistors T1 and T2 in the thin film transistor group described above with reference to FIG. 2 to FIG. 13 may respectively be, for example, the transistors T2a and T4a in the sub-pixel driving circuit, or may respectively be the transistors T5a and T10a, and the present disclosure is not limited thereto.

In some embodiments, the pixel size may be reduced by stacking thin film transistors in the array substrate. In addition, using oxide thin film transistors as switching transistors may reduce leakage current, thereby reducing the size of the storage capacitor accordingly to further reduce the pixel size; as such, the resolution of the display device may be effectively increased. On the other hand, the sub-pixel driving circuit using an inverter circuit module constituted by transistors T8a to T10a can reduce the number of transistors in the PWM module, thereby also improving the resolution. In some embodiments, the display device 600 is a micro-LED display device, and the resolution thereof may be increased to more than 300 PPI. Moreover, by providing a signal shielding structure between the stacked thin film transistors, signal crosstalk between adjacent thin film transistors can be effectively shielded, thereby allowing each thin film transistor to work reliably and stably, and further realizing the display function of a high-resolution display device.

The pixel driving circuit of the present disclosure is described above by taking 10T2C circuit as an example, but the present disclosure is not limited thereto. It should be understood that, the present disclosure may adopt any suitable pixel driving circuit based on product requirements, such as 2T1C, 4T1C, 6T1C, 7T1C or 8T1C pixel driving circuit. The signal shielding structure of the embodiments of the present disclosure may be applied in various pixel driving circuits and is disposed between stacked thin film transistors to shield signal crosstalk between adjacent thin film transistors.

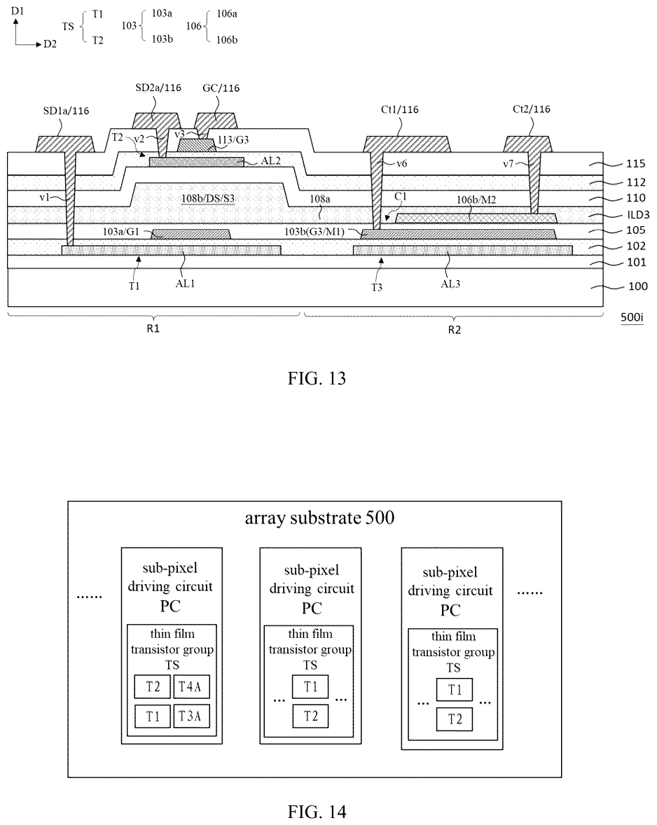

FIG. 16 illustrates a schematic block diagram of a display device D according to some other embodiments of the present disclosure.

In some embodiments, the display device D may be an OLED display device, and may be or include any one of the above-mentioned array substrates 500a-500i. For example, the display device D may include a plurality of pixel units arranged in an array. For example, each pixel unit may include a sub-pixel driving circuit PC and a light-emitting device, and the sub-pixel driving circuit PC is configured to drive the light-emitting device to emit light. The sub-pixel driving circuit PC may include a plurality of thin film transistors and capacitors. The plurality of thin film transistors may have a thin film transistor group TS, and a signal shielding structure is disposed between adjacent thin film transistors of the thin film transistor group TS to shield signal crosstalk between the adjacent thin film transistors. The light-emitting device may include an anode, a cathode, and an organic light-emitting layer between the anode and cathode.

In the above-mentioned embodiments, the array substrate is applied to LED and OLED display devices, which is described as an example for illustration, but the present disclosure is not limited thereto. In some other embodiments, the array substrate of the present disclosure may also be applied to other types of display devices. It should be understood that, the concept of providing the signal shielding structure between stacked thin film transistors in the embodiments of the present disclosure may be applied to any display device or other types of electronic devices including stacked thin film transistors.

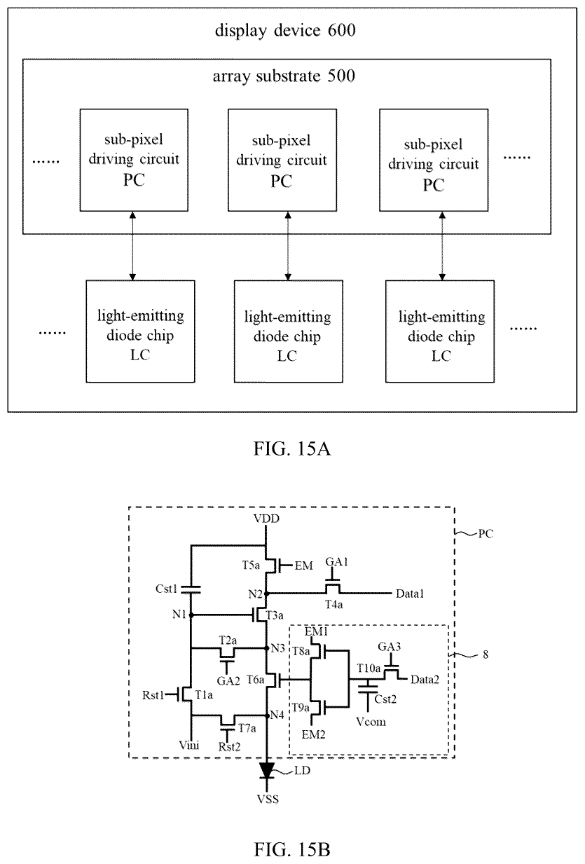

FIG. 17 illustrates an SEM image of an array substrate according to some embodiments of the present disclosure. FIG. 17 is, for example, an array substrate corresponding to the embodiment shown in FIG. 2, and for the sake of brevity, FIG. 17 mainly illustrates the gate electrode G1 of the thin film transistor T1, the metal shielding layer MS, the gate electrode G2 of the thin film transistor T2, the active layer AL2, the gate electrode G3, and the insulation/dielectric material layer between these material layers.

Referring to FIG. 2 and FIG. 17, in some embodiments, the insulation layer 105 formed on the metal layer 103a extends along the surface of the metal layer 103a, and is conformal with the metal layer 103a, for example; that is, the insulation layer 105 located on the gate electrode G1 has substantially the same topography as the gate electrode G1. As a result, the metal shielding layer MS formed on the insulation layer 105 also has substantially the same topography as the underlying material layer (gate electrode G1).

For example, the gate electrode G1 has a body part G1a and an end part G1e, the body part G1a has a substantially uniform thickness, and the end part G1e is close to the sidewall/edge of the gate electrode G1. For example, the gate electrode G1 has an inclined sidewall, and the thickness of the end part G1e may gradually decrease as the end part G1e being away from the body part G1a. The metal shielding layer MS is located on a side of the gate electrode G1 away from the base substrate, and includes a first portion MS1, a second portion MS2 and a third portion MS3 connected to each other; the first portion MS1 and the second portion MS2 are respectively located on sides of the body part G1a and the end part G1e of the gate electrode G1 away from the base substrate, and the orthographic projections of the first portion MS1 and the second portion MS2 on the base substrate respectively overlap with the orthographic projections of the body part G1a and the end part G1e of the gate electrode GI on the base substrate; and the third portion MS3 extends beyond the end part G1e and an edge of the gate electrode in a direction parallel to the main surface of the base substrate.

In some embodiments, as shown in FIG. 17, the metal shielding layer MS may laterally surround the gate electrode G1 and the metal layer 103a in which the gate electrode G1 is located in the direction parallel to the main surface of the base substrate, and the orthographic projection of the gate electrode GI on the base substrate may be covered (e.g., completely covered) by the orthographic projection of the metal shielding layer MS on the base substrate. In this way, the metal shielding layer MS can effectively shield the influence of the signal of the gate electrode G1 on the overlying thin film transistor T2, thereby effectively preventing signal crosstalk.

In some embodiments, components such as the gate electrode G2, the active layer AL2, the gate electrode G1 of the thin film transistor T2 located on a side of the metal shielding layer MS away from the base substrate also have a topography similar to that of the underlying material layer. For example, the gate electrode G2 has a first portion G2a, second portions G2b and G2b′, and a third portion G2c connected to each other; the orthographic projections of the first portion G2a, the second portions G2b and G2b′, and the third portion G2c of the gate electrode G2 on the base substrate respectively overlap with the orthographic projections of the first portion MS1, the second portion MS2, and the third portion MS3 of the metal shielding layer MS on the base substrate. In some embodiments, the gate electrode G2 may have an asymmetric structure. For example, the second portions G2b and G2b′ located on opposite sides of the first portion G2a of the gate electrode G2 may have different thicknesses, the thickness of the second portion G2b′ may gradually decrease as the second portion G2b′ being away from the first portion G2a, the third portion G2c may be only located on a side of the second portion G2b away from the first portion G2a, and there may be no third portion G2c located on a side of the second portion G2b′ away from the first portion G2a. However, the present disclosure is not limited thereto.

In some embodiments, the gate electrode G3 also has an asymmetric structure; for example, the gate electrode G3 has a body part G3a and end parts G3b and G3b′ located on opposite sides of the gate electrode G3a in the direction parallel to the main surface of the base substrate; for example, the thickness of the body part G3a may be different from the thickness of the end part G3b or G3b′, and the thickness of the end part G3b or G3b′ may gradually decrease as being away from the body part G3a. The end part G3b may extend beyond the edge of the gate electrode G1 in the direction parallel to the main surface of the base substrate, and the end part G3b′ may be located directly above the gate electrode G1 without extending beyond the edge of the gate electrode G1. However, the present disclosure is not limited thereto.

In some embodiments, the thickness of the metal shielding layer MS is less than the thickness of the metal layer where the gate electrodes G1, G2, and G3 are located. For example, the thickness of the metal shielding layer MS may be less than or equal to 103 nm. Setting the metal shielding layer MS to be thin may avoid or reduce a great impact on the topography of the overlying structure due to the adding of the metal shielding layer MS, and may also avoid or reduce the impact on the overall thickness of the array substrate.

In some embodiments, as shown in FIG. 17, among the plurality of metal layers as illustrated, the metal shielding layer MS has the largest lateral dimension. For example, the metal shielding layer MS laterally extends beyond the edges of the gate electrode G1 (metal layer 103a), the gate electrode G2 (metal layer 109), and the gate electrode G3 (metal layer 113) in the direction parallel to the main surface of the base substrate. The orthographic projections of the gate electrode G1 (metal layer 103a), the gate electrode G2 (metal layer 109), and the gate electrode G3 (metal layer 113) on the base substrate may all be located within the orthographic projection of the metal shielding layer MS on the base substrate, and an area of the orthographic projection of the metal shielding layer MS on the base substrate may be larger than an area of the orthographic projection of each of the gate electrode G1 (metal layer 103a), the gate electrode G2 (metal layer 109), and the gate electrode G3 (metal layer 113) on the base substrate. With such a configuration, the signal shielding capability of the metal shielding layer MS can be improved, so that the metal shielding layer MS can effectively shield signal crosstalk between adjacent thin film transistors.

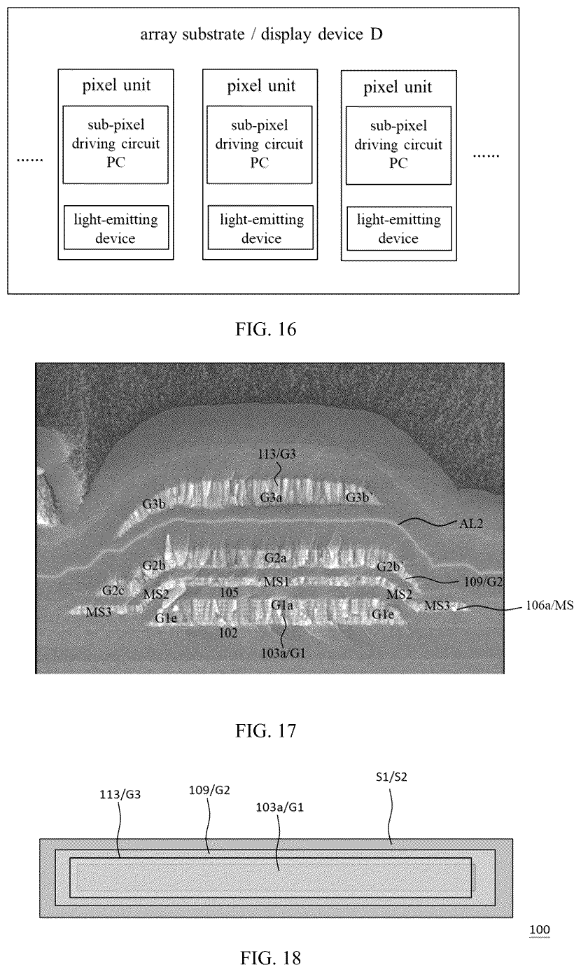

FIG. 18 is a schematic top view illustrating gate electrodes of respective thin film transistors of a thin film transistor group and a signal shielding structure of an array substrate according to some embodiments of the present disclosure. It should be understood that the signal shielding structure S1/S2 and the metal layer where the gate electrodes G2 and G3 are located are shown as transparent in the figure, this is only for the sake of clarity and ease of description, and does not limit these material layers to be transparent materials.

Referring to FIG. 2 to FIG. 13 and FIG. 18, in some embodiments, the orthographic projection of the metal layer 103a where the gate electrode G1 of the thin film transistor T1 is located on the base substrate 100, and the orthographic projections of the metal layer 109 where the gate electrode G2 of the thin film transistor T2 is located and the metal layer 113 where the gate electrode G3 of the thin film transistor T2 is located on the base substrate 100, may all be within a range of the orthographic projection of the signal shielding structure S1 or S2 on the base substrate 100. In some embodiments, an area of the orthographic projection of the signal shielding structure S1 or S2 on the base substrate 100 may be larger than an area of the orthographic projection of the metal layer 103 on the base substrate 100, an area of the orthographic projection of the metal layer 109 on the base substrate 100, and an area of the orthographic projection of the metal layer 113 on the base substrate 100. Through the aforementioned configuration, the signal shielding structure can effectively shield the signal crosstalk between adjacent thin film transistors T1 and T2.

The following statements should be noted:
(1) The drawings of the present disclosure involve only the structure(s) in connection with the embodiment(s) of the present disclosure, and other structure(s) can be referred to common design(s).
(2) In case of no conflict, features in one embodiment or in different embodiments can be combined to obtain new embodiments.

What have been described above are only specific implementations of the present disclosure, the protection scope of the present disclosure is not limited thereto. Any modifications or substitutions easily occur to those skilled in the art within the technical scope of the present disclosure should be within the protection scope of the present disclosure. Therefore, the protection scope of the present disclosure should be based on the protection scope of the claims.

1. An array substrate, comprising:
a base substrate;
a thin film transistor group, disposed on a side of the base substrate, wherein the thin film transistor group comprises a first thin film transistor and a second thin film transistor, the first thin film transistor and the second thin film transistor overlap with each other in a first direction perpendicular to a main surface of the base substrate, the second thin film transistor is disposed on a side of the first thin film transistor away from the base substrate, the first thin film transistor comprises a first active layer and a first gate electrode, and the second thin film transistor comprises a second active layer and a second gate electrode;
a signal shielding structure, disposed between the first thin film transistor and the second thin film transistor in the first direction, wherein an orthographic projection of the first gate electrode on the base substrate is within a range of an orthographic projection of the signal shielding structure on the base substrate; and
a conductive connector, disposed on a side of the signal shielding structure away from the first thin film transistor and connected to the first thin film transistor through a via hole, wherein the via hole does not penetrate through the signal shielding structure, and is spaced apart from the signal shielding structure in a second direction parallel to the main surface of the base substrate.

2. The array substrate according to claim 1, wherein an orthographic projection of at least a portion of the second gate electrode on the base substrate overlaps with the orthographic projection of the first gate electrode on the base substrate, and the orthographic projection of the at least the portion of the second gate electrode on the base substrate is within a range of the orthographic projection of the signal shielding structure on the base substrate.

3. The array substrate according to claim 1, wherein the signal shielding structure is disposed on a side of the first gate electrode away from the first active layer and close to the second thin film transistor.

4. The array substrate according to claim 1, wherein the signal shielding structure comprises a metal shielding layer, and the metal shielding layer is connected to a direct current signal terminal.

5. (canceled)

6. The array substrate according to claim 4,
wherein the second gate electrode comprises a top gate electrode and a bottom gate electrode that are connected to each other, the top gate electrode and the bottom gate electrode are located on opposite sides of the second active layer in the first direction, and the bottom gate electrode is closer to the base substrate than the top gate electrode to the base substrate; and
the metal shielding layer is located between the bottom gate electrode and the first gate electrode.

7. The array substrate according to claim 4, wherein the second gate electrode and the metal shielding layer are located on opposite sides of the second active layer in the first direction, and the metal shielding layer is further configured to adjust a threshold voltage of the second thin film transistor by selecting a direct current signal terminal to which the metal shielding layer is connected.

8. The array substrate according to claim 4, wherein the signal shielding structure further comprises a dielectric shielding unit, and an orthographic projection of the second active layer on the base substrate is within a range of an orthographic projection of the dielectric shielding unit on the base substrate.

9. The array substrate according to claim 8, wherein the metal shielding layer is disposed on a side of the dielectric shielding unit closer to the first thin film transistor, and the metal shielding layer extends beyond an edge of the dielectric shielding unit in a direction parallel to the main surface of the base substrate.

10. The array substrate according to claim 8, wherein the metal shielding layer is disposed on a side of the dielectric shielding unit away from the first thin film transistor, and an orthographic projection of the metal shielding layer on the base substrate overlaps with the orthographic projection of the dielectric shielding unit on the base substrate.

11. The array substrate according to claim 1, further comprising: an interlayer dielectric structure, located between the first thin film transistor and the second thin film transistor in the first direction, wherein the signal shielding structure is embedded in the interlayer dielectric structure or at least comprises a portion of the interlayer dielectric structure.

12. The array substrate according to claim 11, wherein the interlayer dielectric structure comprises a dielectric body part and a dielectric protrusion;
the dielectric body part extends from a first region where the thin film transistor group is located to a second region of the array substrate in the second direction parallel to the base substrate, and the second region is a region other than the first region;
the dielectric protrusion is located in the first region, and protrudes toward the second thin film transistor from a surface of the dielectric body part away from the first thin film transistor, and the dielectric protrusion is served as a dielectric shielding unit and used as at least a portion of the signal shielding structure; and
the via hole penetrates through the dielectric body part.

13. The array substrate according to claim 12, wherein the dielectric body part and the dielectric protrusion comprise different materials, and an interface is between the dielectric body part and the dielectric protrusion; or
wherein the dielectric body part and the dielectric protrusion comprise a same material and are integrally formed.

14. The array substrate according to claim 12, wherein a dielectric constant of the dielectric protrusion is less than a dielectric constant of the dielectric body part.

15-18. (canceled)

19. The array substrate according to claim 12, wherein the signal shielding structure further comprises a metal shielding layer, the metal shielding layer is embedded in the dielectric body part and connected to a direct current signal terminal through a conductive via, and the conductive via is laterally aside the dielectric protrusion in the second direction and extends through a portion of the dielectric body part to connect to the metal shielding layer.

20. The array substrate according to claim 12, wherein an additional metal layer is disposed on a side of the dielectric protrusion away from the dielectric body part and close to the second active layer, and the second gate electrode comprises a top gate electrode located on a side of the second active layer away from the additional metal layer;
wherein the additional metal layer is connected to a direct current signal terminal and served as a metal shielding layer of the signal shielding structure; or
the additional metal layer is connected to the top gate electrode, so as to be served as a bottom gate electrode of the second thin film transistor.

21. The array substrate according to claim 1, further comprising:
a capacitor, disposed on the base substrate and disposed side by side with the first thin film transistor and the signal shielding structure in a direction parallel to the main surface of the base substrate, wherein the capacitor comprises a first electrode plate and a second electrode plate that are opposite to each other,
wherein the array substrate further comprises a first metal material layer, an insulation layer, and a second metal material layer, and the insulation layer is located between the first metal material layer and the second metal material layer;
the first electrode plate and the first gate electrode are located in the first metal material layer, and the second electrode plate is located in the second metal material layer; and
the signal shielding structure comprises at least one of a metal shielding layer and a dielectric shielding unit, and the dielectric shielding unit is located on a side of the insulation layer away from the first metal material layer.

22. (canceled)

23. The array substrate according to claim 21, comprising a first region and a second region, wherein the thin film transistor group is located in the first region, the capacitor is located in the second region, and the second metal material layer extends continuously from the first region to the second region, and is used as both the metal shielding layer and the second electrode plate.

24. The array substrate according to claim 1, comprising a plurality of thin film transistor groups arranged in an array, and each of the plurality of thin film transistor groups is configured to be formed in one sub-pixel driving circuit.

25. The array substrate according to claim 24, wherein the thin film transistor group comprises a first thin film transistor sub-group and a second thin film transistor sub-group arranged side by side in a direction parallel to the base substrate;
the first thin film transistor sub-group comprises the first thin film transistor and the second thin film transistor;
the second thin film transistor sub-group comprises a third thin film transistor and a fourth thin film transistor overlapped in the first direction, and an additional signal shielding structure is disposed between the third thin film transistor and the fourth thin film transistor.

26-27. (canceled)

28. A display device, comprising the array substrate according to claim 1, and
a light-emitting device,
wherein the light-emitting device is connected to a sub-pixel driving circuit comprising the thin film transistor group, and the sub-pixel driving circuit is configured to drive the light-emitting device to emit light.

29-39. (canceled)
